(19) United States
(12) Patent Application Publication
(10) Pub. No.: US 2025/0046695 A1
(43) Pub. Date: Feb. 6, 2025

(54) METHOD FOR MANUFACTURING AN ELECTRICALLY CONDUCTIVE CHANNEL STRUCTURE IN A SUBSTRATE AND INTERPOSER ARRANGEMENT

(71) Applicant: Fraunhofer-Gesellschaft zur Förderung der angewandten Forschung e.V., München (DE)

(72) Inventors: Wolfgang REINERT, Itzehoe (DE); Hans-Joachim QUENZER, Itzehoe (DE); Nils BURMEISTER, Itzehoe (DE)

(73) Assignee: Fraunhofer-Gesellschaft zur Förderung der angewandten Forschung e.V., München (DE)

(21) Appl. No.: 18/793,737

(22) Filed: Aug. 2, 2024

(30) Foreign Application Priority Data
Aug. 4, 2023 (DE) 102023207522.9

(51) Int. Cl. H01L 23/498; H01L 21/48; H01L 23/373

(52) U.S. Cl. CPC H01L 23/49827; H01L 21/486; H01L 23/3736; H01L 23/49838; H01L 23/49866

(57) ABSTRACT

A method for manufacturing an electrically conductive channel structure in a substrate has the following steps: (−) providing a stack arrangement in a clamping device, the stack arrangement having a substrate provided with a channel structure, a metal film having an aluminum material (=also an aluminum material alloy) on the substrate, and a compressible sealing element which at least laterally surrounds the metal film while exerting pressure, (−) applying a planar-acting mechanical process pressure and a process temperature to the stack arrangement with the clamping device in order to melt the metal film having the aluminum material at the process temperature and to introduce it into the channel structure as metallic filling material by means of the planar-acting mechanical process pressure, and (−) cooling the stack arrangement to solidify the introduced metallic filling material and to obtain the electrically conductive channel structure filled with the metallic filling material.

### CROSS-REFERENCE TO RELATED APPLICATION

This application claims priority from German Patent Application No. 102023207522.9, which was filed on Aug. 4, 2023, which is incorporated herein by reference in its entirety.

### TECHNICAL FIELD

The present invention relates to a method for manufacturing an electrically conductive channel structure in a substrate, for example in a glass substrate or silicon substrate, and to an interposer arrangement. The interposer arrangement may be manufactured using the manufacturing method described.

The present invention relates to conductive channel structures (through vias or vias, blind holes, 3D structures) made of/with an aluminum material in a substrate which may have a glass, quartz, sapphire, ceramic or semiconductor material. In particular, the present invention relates to TGVs (through glass vias) or conductive channel structures (vias or blind holes) made of/with an aluminum material in glass substrates. The present invention further relates to TSVs (TSV=through silicon vias) or conductive channel structures (vias or blind holes) made of/with an aluminum material in silicon substrates.

The present invention further relates to an interposer arrangement having an electrically conductive channel structure extending at least partially through a substrate and comprising an aluminum material or an aluminum material alloy. The interposer arrangement may, for example, be manufactured using the method for manufacturing an electrically conductive channel structure in a substrate.

### BACKGROUND OF THE INVENTION

In semiconductor technology, the term “via” (or “through via”) through a substrate, e.g. a silicon or glass substrate, or PCB (printed circuit board) refers to a vertical electrical connection made of metal through the substrate (also wafer or chip) in order to establish an electrical connection between two or more metallization levels, on opposite sides of the substrate, for example.

Various competing technologies are known for the production of electrically conductive through contactings or vias through wafer substrates, which are based on the use of either solder (soft solder) or electroplated copper for filling the vias. Such vias include an opening (hole) through the substrate, with the opening being plated with copper which forms an electrical connection through the layers of the substrate. Such through contactings also use an adhesive layer on the via wall, which makes the resulting manufacturing process relatively complex.

The micro technology processes used so far also have the character of a 2.5-D technology, i.e. only 2D structures can actually be structured lithographically, which are vertically extended in depth, e.g. by high-rate etching. This limits the design options to purely vertical vias, wherein the use of adhesion promoters also results in relatively poor high-frequency properties due to the skin effect (current displacement effect), as the current through the vias concentrates with an increasing frequency in the surface (in the edge area), i.e. in the less conductive adhesion promoter. Furthermore, the restriction to purely vertical vias also results from the fact that the sidewall metallization, which is normally used for electroplating copper, may only be applied to accessible (i.e. vertically extending) surfaces, i.e. surfaces which are not covered by other structures.

Alternative manufacturing processes use, for example, pin vias embedded in glass made of highly conductive silicon, molybdenum or tungsten, although these materials are less suitable for high-frequency and quantum technology applications.

Thus, the object underlying the present invention is to provide an improved method for manufacturing electrically conductive channel structures in a substrate and further to provide a correspondingly improved interposer arrangement (which may, for example, be manufactured using the improved manufacturing method).

### SUMMARY

According to an embodiment, a method for manufacturing an electrically conductive channel structure in a substrate may have the steps of: providing a stack arrangement in a clamping device, the stack arrangement comprising a substrate provided with a channel structure, a metal film comprising an aluminum material on the substrate, and a compressible sealing element configured to surround the metal film at least laterally while exerting pressure, exerting a planar-acting mechanical process pressure and a process temperature on the stack arrangement with the clamping device in order to melt the metal film comprising the aluminum material at the process temperature and to introduce it into the channel structure as metallic filling material by means of the planar-acting mechanical process pressure, and cooling the stack arrangement to solidify the introduced metallic filling material and to obtain the electrically conductive channel structure filled with the metallic filling material.

According to another embodiment, an interposer arrangement may have: a substrate comprising an electrically and/or thermally conductive channel structure extending at least partially through the substrate, wherein the channel structure comprises an aluminum material or an aluminum material alloy, and wherein the channel structure extends from a main surface region of the substrate into the substrate, and wherein the aluminum material or the aluminum material alloy comprises aluminum as the main component of at least 80% in order to have a resulting melting point of at least 420° C. or between 420° C. and 850° C. as brazing hard solder.

In accordance with an embodiment, a method for manufacturing an electrically conductive channel structure in a substrate comprises the following steps:—providing a stack arrangement in a clamping device, the stack arrangement comprising a substrate provided with a channel structure, a metal film (or sheet) having an aluminum material (=also an aluminum material alloy) on the substrate, and a compressible sealing element configured to surround the metal film (at least) laterally while exerting pressure,—exerting a planar-acting (or laminar-acting) mechanical process pressure and a process temperature on the stack arrangement with the clamping device to melt the metal film comprising the aluminum material at the process temperature and to introduce it into the channel structure as metallic filling material by means of the planar-acting mechanical process pressure, and—cooling the stack arrangement to solidify the introduced metallic filling material and to obtain the electrically conductive channel structure filled with the metallic filling material.

The compressible sealing element may, for example, be configured as an overlapping surface seal or as an enclosing ring seal. The compressible sealing element may also be configured for high-temperature applications at the process temperature (as a compressible high-temperature sealing element).

The present invention is thus based on the finding that a novel, advantageous method for manufacturing electrically conductive channel structures (e.g. in the form of feedthroughs, 3D (3-dimensional) structures, passive components or blind holes, etc.) in a substrate can be carried out, wherein pressure filling of the channel structures, e.g. through holes, blind holes or 3D structures, in a dielectric substrate with an aluminum melt can be performed (based on a metal film comprising an aluminum material or an aluminum material alloy). Channel structures with different geometries in terms of hole diameter, flank angle, channel inclination and channel length may be filled.

Furthermore, the inventive method for manufacturing electrically conductive channel structures in a substrate obtains or produces a corresponding interposer arrangement.

In accordance with a further embodiment, an interposer arrangement comprises a substrate having an electrically and/or thermally conductive channel structure extending at least partially through the substrate, the channel structure comprising an aluminum material or an aluminum material alloy, wherein the electrically and/or thermally conductive channel structure extends from a main surface region of the substrate into the substrate.

The aluminum material or the aluminum material alloy has at least 80% or 90% aluminum as its main component in order to have a resulting melting point of at least 420° C. (or 520° C.) or between 420° C. (or 520° C.) and 850° C. as hard solder.

### BRIEF DESCRIPTION OF THE DRAWINGS

Embodiments of the present invention are explained in more detail below with reference to the accompanying drawings and figures, in which:

FIG. 1 is a schematic flow chart of the inventive manufacturing method in accordance with an embodiment;

FIG. 2A is an exemplary principle flow diagram of the inventive manufacturing method, e.g. having an overlapping surface seal, in accordance with a further embodiment;

FIG. 2B is an exemplary principle flow diagram of the inventive manufacturing method, e.g. with an enclosing ring seal, in accordance with a further embodiment;

FIG. 3A shows exemplary Al-TGVs (aluminum through-glass vias) in glass (e.g. quartz glass) produced by the manufacturing method of FIG. 1 or FIGS. 2A-2B;

FIG. 3B is a detailed representation of the interface connection between the conductive AL filling (of the Al-TGV) and glass (e.g. borosilicate glass), which was produced by the manufacturing method of FIG. 1 or FIGS. 2A-2B;

FIGS. 4A-4B show an example of an Al—Cu melt filling in a quartz substrate (produced by the manufacturing method of FIG. 1 or FIGS. 2A-2B) in accordance with an embodiment;

FIGS. 5A-5C show an exemplary procedure for obtaining improved electrical properties of the vias (Al-TGVs) in accordance with an embodiment;

FIG. 5D shows another exemplary procedure for obtaining improved electrical properties of the vias (Al-TGVs) in accordance with an embodiment;

FIGS. 6A-6I show exemplary geometries of channel structures with different dimensions and wall angles (for filling with the inventive manufacturing method of FIG. 1 or FIGS. 2A-2B);

FIG. 7 is a schematic representation of further possible substrate topologies for use in the inventive manufacturing method of FIG. 1 or FIGS. 2A-2B;

FIGS. 8A-8C are schematic representations of exemplary interposer arrangements (with possible substrate topologies) in accordance with further embodiments, which may be obtained, for example, using the inventive manufacturing method of FIG. 1 or FIGS. 2A-2B;

FIG. 9A shows exemplary 3D channel structures (e.g. an aluminum-filled 3D helix), produced by the inventive manufacturing method of FIG. 1 or FIGS. 2A-2B in accordance with an embodiment;

FIG. 9B is a magnified 3D X-ray tomography image of the aluminum-filled 3D helix of FIG. 9A;

FIG. 10 is a perspective view (3D view) of a component (in the form of a metal-filled helix) in a glass substrate produced by the manufacturing method of FIG. 1 or FIGS. 2A-2B in accordance with an embodiment;

FIG. 11 is a perspective view of a component (in the form of a thin-film getter structure with via contacting) produced by the manufacturing method of FIG. 1 or FIGS. 2A-2B in accordance with an embodiment;

FIGS. 12A-12B are a perspective view and a cross-sectional view of a component (in the form of a capacitor structure) produced by the manufacturing method of FIG. 1 or FIGS. 2A-2B in accordance with an embodiment;

FIGS. 13A-13C are cross-sectional views of packaged components (e.g. MEMS, sensors and/or ICs) with the Al-TGVs (produced by the manufacturing method of FIG. 1 or FIGS. 2A-2B) for electrical connection (as electrical via) and/or thermal connection (for heat dissipation) in accordance with an embodiment;

FIG. 14 is an exemplary principle flow diagram for further processing (on the wafer level) of the stack arrangement obtained by the manufacturing method of FIG. 1 or FIGS. 2A-2B in accordance with an embodiment; and

FIGS. 15-22 show exemplary, principle flow diagrams relating to further and alternative procedures for manufacturing an electrically conductive channel structure by introducing a metallic filling material in accordance with further embodiments.

Before embodiments of the present invention are explained in more detail below referring to the drawings, it is pointed out that identical elements, objects, functional blocks and/or process steps or those of equal function or equal effect are provided with the same reference numerals in the different figures so that the description of these elements, objects, functional blocks and/or process steps (with the same reference numerals) shown in different embodiments is interchangeable or mutually applicable.

### DETAILED DESCRIPTION OF THE INVENTION

In the following description, the description of an element made of a material, such as a glass, quartz, sapphire, ceramic or semiconductor material, means that the element comprises this material, i.e. is formed at least partially or completely from the semiconductor material.

It will be understood that when an element is described to be “connected” or “coupled” to another element, it may be directly connected or coupled to the other element or intermediate elements may be present. In contrast, if an element is described to be “directly” “connected” or “coupled” to another element, no intermediate elements are present. Other expressions used to describe the relationship between elements should be interpreted in the same way (e.g. “between” versus “directly between”, “adjacent” versus “directly adjacent”, etc.).

To simplify the description of the various embodiments, at least some of the figures have a Cartesian coordinate system x, y, z, wherein the directions x, y, z are arranged orthogonally to each other. In embodiments, the x-y plane corresponds to the main surface region of a carrier or substrate (=reference plane=x-y plane), wherein the vertical upward direction with respect to the reference plane (x-y plane) corresponds to the “+z” direction, and wherein the vertical downward direction with respect to the reference plane (x-y plane) corresponds to the “−z” direction. In the following description, the term “lateral” means a direction parallel to the x and/or y direction, i.e. parallel to the x-y plane, whereas the term “vertical” means a direction parallel to the +/−z direction.

In the context of the present description, terms and/or text passages in brackets are to be understood to be further explanations, exemplary implementations, additions and/or exemplary alternatives (to the preceding term or the preceding text passage).

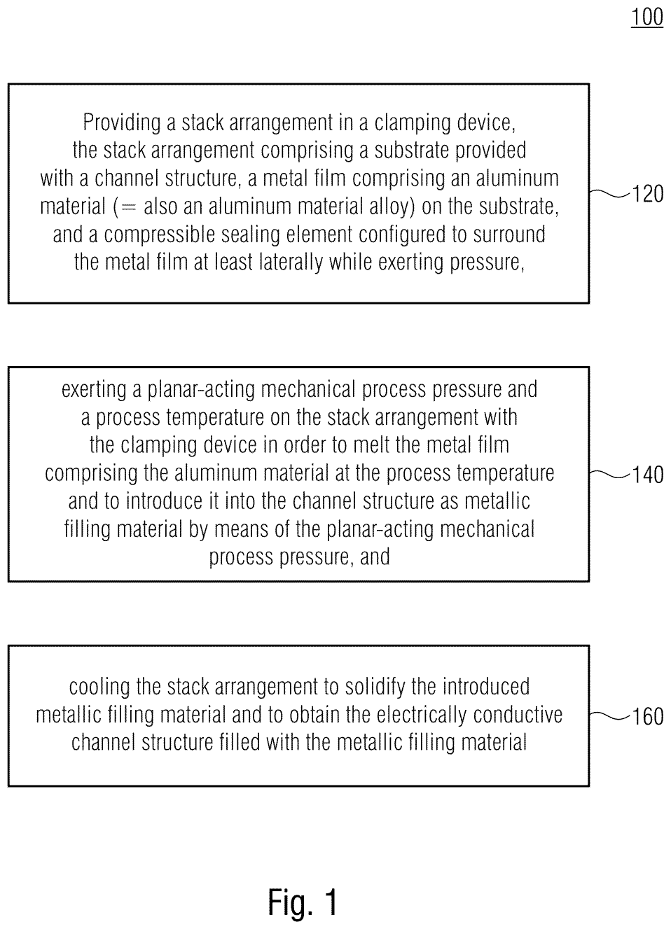

In the following, a schematic flow chart of the inventive method 100 for manufacturing an electrically conductive channel structure in a substrate is described by way of example with reference to FIG. 1. The arrangement obtained in the manufacturing method 100, i.e. a substrate having electrically conductive channel structures or vias, may then be used, for example, as a so-called interposer arrangement 50 for electronic components for their rerouting and/or heat dissipation, etc.

With reference to the method 100 of FIG. 1, a stack arrangement is provided in a clamping device (clamping arrangement) in step 120, wherein the stack arrangement comprises a substrate provided with a channel structure, a metal film having an aluminum material or an aluminum material alloy on the substrate, and a compressible sealing element which surrounds the metal film (at least) laterally when pressure is applied over its surface.

The compressible sealing element may, for example, be configured as an overlapping surface seal or as an enclosing ring seal. The compressible sealing element may also be configured for high-temperature applications at the process temperature (as a compressible high-temperature sealing element).

In a (subsequent) step 140, a planar-acting (or laminar-acting) mechanical process pressure and a process temperature are exerted on the stack arrangement with (by means of) the clamping device in order to melt (liquefy) the metal film comprising the aluminum material at the process temperature and to introduce it into the channel structure as metallic filling material by means of the planar-acting mechanical process pressure.

In accordance with an embodiment, in step 140, for example, the liquefied material of the metal film is enclosed between the compressible surface sealing element and the substrate provided with the channel structures in that the compressible surface sealing element covers the metal film and overlaps the edge region of the metal film and thus surrounds (covers and laterally surrounds) the metal film while exerting pressure up to the substrate. This may prevent the liquefied/melted material of the metal film from escaping laterally through the surrounding surface sealing element.

In accordance with a further embodiment, in step 140, for example, the liquefied material of the metal film is enclosed between a first tool (e.g. pressing punch) of the clamping device and the substrate provided with the channel structures, wherein a compressible ring sealing element (=an enclosing ring seal) surrounds (encloses) the edge region of the metal film so that the ring sealing element surrounds the metal film laterally (between the substrate and the first tool) while exerting a pressure. This may prevent lateral leakage (escape) of the liquefied/molten material of the metal film through the surrounding ring sealing element.

In a subsequent step 160, the stack arrangement is cooled to re-solidify (harden) the introduced metallic filling material (i.e. the metallic filling material melted during introduction) to obtain the electrically conductive channel structure filled with the (solidified) metallic filling material.

In accordance with an embodiment, the channel structure may be configured as at least one through structure, as at least one blind hole structure or as at least one 3D structure in the substrate.

In accordance with an embodiment, the metal film may have the aluminum material as the main component (≥80%) for a resulting melting point of at least 420° C. (or 520° C.) or between 420° C. (or 520° C.) and 850° C. In accordance with an embodiment, the (increased) process temperature may be set to a value of at least 10 K or 20 K above the melting temperature of the metal film comprising the aluminum material.

In accordance with an embodiment, the channel structure may have a coating (wall coating) comprising nitride material, e.g. with AlN (aluminum nitride), SiN (silicon nitride) or TiN (titanium nitride) with a thickness in a range of 2 to 100 nm.

In accordance with an embodiment, the compressible sealing element may be configured as a compressible surface sealing element. In accordance with an embodiment, the surface sealing element may cover the metal film and have a lateral projection (laterally beyond the metal film), i.e. overlap the metal film, in order to enclose the metal film up to the substrate when the mechanical process pressure is exerted.

In accordance with an embodiment, the compressible sealing element may be configured as a compressible ring sealing element, wherein the ring sealing element surrounds the edge region of the metal film and laterally encloses the metal film when pressure is exerted.

In accordance with an embodiment, the sealing element may be configured as a reusable high temperature seal or gasket. In accordance with an embodiment, the sealing element may comprise or consist of a graphite film or a structured (annular) graphite film having a thickness in a range from 0.3 to 1 mm or about 0.5 mm.

In accordance with an embodiment, the clamping arrangement may comprise a first and a second tool, wherein the stack arrangement is arranged between the first and the second tool. In accordance with an embodiment, the step of exerting a mechanical pressure between the first and second tools may be performed having a contact pressure in a range from 10 N/cm² to 600 N/cm². In accordance with an embodiment, the first and/or second tool may be configured to heat the stack arrangement to the process temperature.

In accordance with an embodiment, the first tool may be configured as a press punch (or stamp) and the second tool as a counter substrate, wherein a main surface region of the second tool facing the substrate has a surface roughness having a mean roughness value Rₐ or an average roughness depth R_{Z} of between 0.5 and 10 μm or of about 3 μm.

In accordance with an embodiment, the main surface region of the second tool facing the substrate may have a coating to provide the surface roughness of the main surface region of the second tool facing the substrate. This coating may prevent adhesion of the molten aluminum and, at the same time, adhesion of the hot glass substrate. In accordance with an embodiment, the coating may comprise a boron nitride material.

In accordance with an embodiment, the surface roughness of the main surface region of the second tool adjacent to the substrate may be/is selected to be effective as a flow stop for the molten metal and to allow lateral escape of gas present in the channel structure.

In accordance with an embodiment, the substrate may comprise or consist of a glass, quartz, sapphire, ceramic or semiconductor material.

In accordance with an embodiment, the method 100 may further comprise removing excess metallic filling material on one side on a main surface region or on both sides of both opposing main surface regions of the substrate. In accordance with an embodiment, removing the excess material may be performed by means of a CMP (chemical mechanical polishing) process.

In accordance with an embodiment, the method may further comprise removing the stack arrangement from the clamping arrangement and removing the sealing element from the substrate.

In accordance with an embodiment, the method may further comprise performing metallization on one or both sides by means of a thin film deposition process to obtain a metallization structure electrically connected to the conductive channel structure on one or both main surface regions of the substrate configured with the conductive channel structure, via a lithographic patterning process and a subsequent etching step.

According to the invention, a novel, advantageous method for manufacturing electrically conductive channel structures, e.g. in the form of feedthroughs, 3D structures, passive components or blind holes, etc., in a substrate is thus obtained, wherein pressure filling of the channel structures, e.g. through-holes in a dielectric substrate, is carried out with an aluminum melt (based on a metal film comprising an aluminum material or an aluminum material alloy). Channel structures with different geometries in terms of hole diameter, flank angle, channel inclination and channel length may be filled.

To achieve this, the method first provides a stack arrangement in a clamping device, the stack arrangement comprising a substrate provided with a channel structure, a metal film comprising an aluminum material (or an aluminum material alloy) on the substrate, and a compressible sealing element. The compressible sealing element surrounds (encloses) the metal film under pressure at least laterally (as a ring seal) or encloses the metal film up to the substrate (as a surface seal).

A planar-acting mechanical process pressure and an (increased) process temperature are then exerted on the stack arrangement by means of the clamping device in order to melt the metal film comprising the aluminum material at the process temperature and to introduce or press it into the channel structure as metallic filling material by means of the planar-acting mechanical process pressure. Finally, the stack arrangement is cooled in order to solidify the introduced metallic filling material and to obtain the electrically conductive channel structure filled with the metallic filling material.

In this context, it is to be noted that aluminum acts as its own adhesion promoter to glass, quartz, ceramic or sapphire substrates. Bonding to silicon substrates and oxidized silicon substrates is also possible. Providing an additional adhesion promoter layer may therefore be omitted or is no longer necessary, which not only makes manufacturing the aluminum feedthrough (Al-Via) much easier compared to conventional manufacturing methods, but also makes filling real 3D structures possible at all.

Sidewall wetting may optionally be improved by dielectric coatings. Conformal deposition ALD (atomic layer deposition) technology or LP-CVD (low-pressure chemical vapor deposition) technology is particularly suitable for this purpose. Suitable dielectric layer materials for this are, for example, aluminum nitride (AlN), aluminum oxide (Al₂O₃), silicon nitride (SiN), titanium nitride (TiN) etc., e.g. having a thickness in the range from 2 to 100 nm or from 30-50 nm.

The aluminum wettability of the channel structure may therefore be influenced favorably by previously coating it with SiN, AlN, TIN, etc. using an LP-CVD or ALD process. The coating thicknesses are in the range from 2 nm to 100 nm, or (advantageously) in the range from 30 to 50 nm. The (conformal) pre-coating may be used either to fill smaller via diameters (in a range of 5 to 15 μm) at the same process temperature and pressurization or, in the case of larger via diameters, to reduce in particular the pressurization entailed.

Since aluminum is very ductile (=has the property of deforming plastically under load before failing), aluminum can be pressed quite easily into the opening(s) in the substrate in molten form by a hot-fill process or hot-filling process without the very large differences in the thermal expansion coefficients between the substrate material, e.g. glass, silicon, etc., and the aluminum material or the aluminum alloy leading to destruction, cracks in the substrate or detachment at the interface between the metal and the substrate.

The filling process of the hole and/or channel structures may be improved by applying a suction vacuum (=by applying an atmospheric negative pressure) to remove gases in the hole and/or channel structure or by introducing a protective gas atmosphere to prevent hot oxidation, especially of the wetting front. In the case of complex-shaped hole and/or channel structures (e.g. 3D structures), evacuating the channel structures before filling, e.g. from two opposing channel entrances simultaneously, can prevent unwanted gas cavities in the course of the channel to be filled.

The particularly tight interface connection between the substrate (e.g. a dielectric substrate) and the aluminum filling also opens up the possibility of being able to manufacture hermetically sealed vias.

The method 100 is applicable for sequentially filling individual hole structures, groups of hole arrangements (chips/modules) or all hole structures 12-1 present on a substrate 12 in a common parallel filling process step.

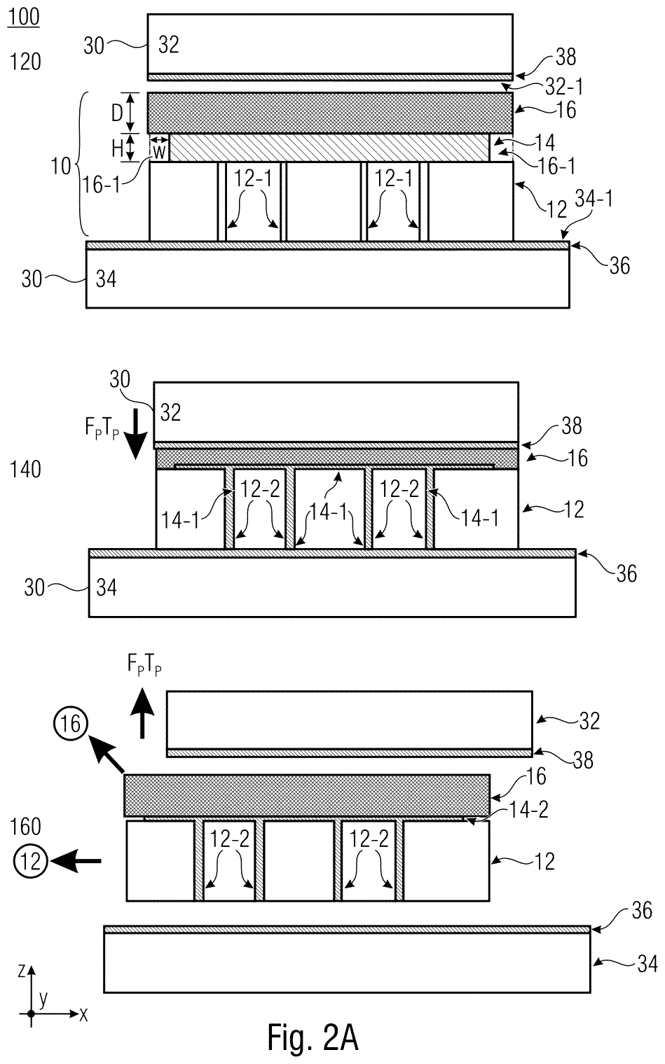

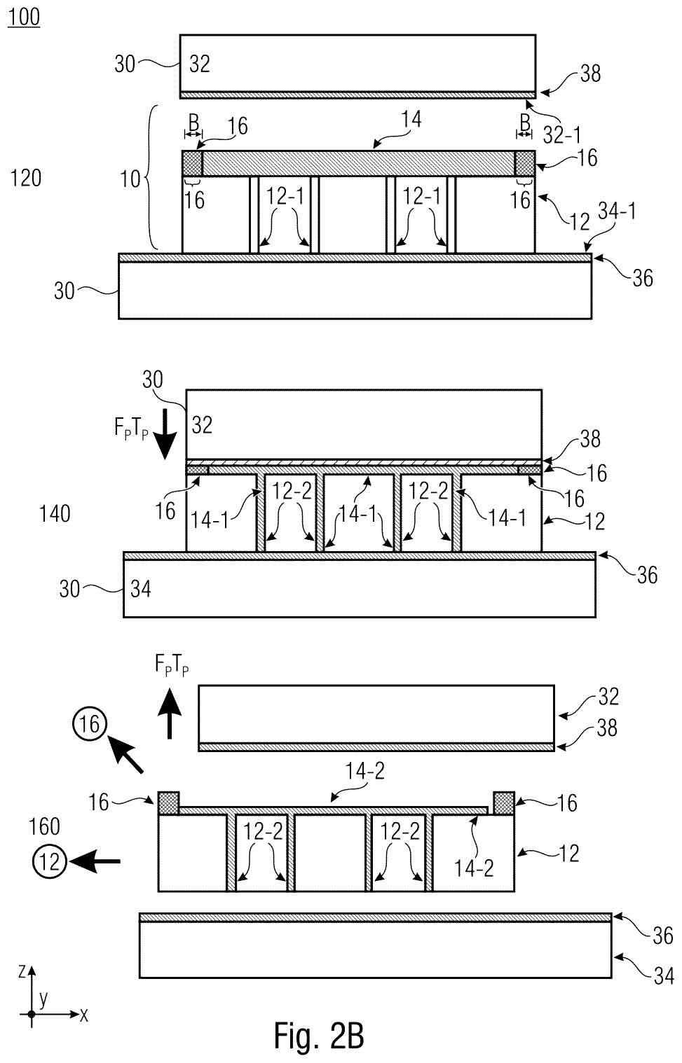

FIG. 2A shows an exemplary principle flow diagram of the inventive method 100 for manufacturing an electrically conductive channel structure 12-2 in a substrate 12, for example using overlapping surface sealing.

FIG. 2A thus shows a possible implementation of the various method steps of the schematic flow chart of the manufacturing method 100 shown in FIG. 1. The arrangement obtained in the manufacturing method 100, i.e. a substrate having electrically conductive channel structures or vias, may then be used, for example, as a so-called interposer arrangement 50 for electronic components, such as a rerouting interposer, as a conductive via, as a (passive) electrical component or for heat dissipation, etc.

Referring to the method 100 of FIG. 2A, in step 120, a stack arrangement 10 is provided in a clamping device 30 (clamping arrangement), wherein the stack arrangement 10 comprises a substrate 12 provided with a channel structure 12-1, a metal film 14 comprising an aluminum material or an aluminum material alloy on the substrate 12, and a compressible surface sealing element 16 which covers the metal film 14 and surrounds the metal film 14 while exerting a (planar-acting) pressure up to the substrate 12.

In accordance with the embodiment of the manufacturing method 100 shown in FIG. 2A, the clamping device 30 may have a first and a second tool 32, 34, wherein the stack arrangement 10 is arranged or clamped (flush) between the first and second tools 32, 34 of the stack arrangement 30.

In a (subsequent) step 140, a planar-acting mechanical process pressure F_{P} and a process temperature T_{P} are then exerted on the stack arrangement 10 with (by means of) the clamping device 30 in order to melt (liquefy) the metal film 14 comprising the aluminum material at the process temperature T_{P} and to introduce it into the channel structure(s) 12-1 as metallic filling material 14-1 by means of the planar-acting mechanical process pressure F_{P}.

For example, in step 140, the liquefied material 14-1 of the metal film 14 is enclosed between the compressible surface sealing element 16 and the substrate 12 provided with the channel structure(s) 12-1 so as to prevent lateral leakage (escape) of the liquefied (molten) material 14-1 of the metal film 14 through the surrounding surface sealing element 16.

The compressible surface sealing element may cover the metal film at least partially or completely, wherein, for example, at least the (entire) edge region of the metal film is (completely) overlapped by the compressible surface sealing element 16.

In accordance with an embodiment, the surface sealing element may cover the metal film and have a lateral overlap laterally beyond the edge of the metal film, wherein this overlap of the surface sealing element 14 may, beyond the edge region of the metal film may, have, for example, an annular, circumferential thickening or bulge (protrusion) 16-1 which extends (as a lowered edge region of the surface seal) to the substrate. The surface sealing element may thus already completely enclose the metal film without exerting a planar-acting mechanical process pressure F_{P}.

In subsequent step 160, the stack arrangement 10 is cooled to re-solidify (solidify) the introduced metallic (molten) filling material 14-1 to obtain the electrically conductive channel structure(s) 12-2 filled with the (solidified) metallic filling material 14-1.

Thus, in the exemplary manufacturing method 100 shown in FIG. 2A, aluminum pressure melt filling of the channel structures 12-1 is performed in the substrate 12. Here, the (second) tool 34 of the clamping device 30 arranged on the substrate 12 serves, for example, as a counter substrate to obtain a flow stop (or a flow stop function) during the melt filling process, wherein the compressible high-temperature seal 16 is provided as an overlapping boundary or enclosure to cause lateral leakage or escape of the liquefied (molten) material 14-1 of the metal film 14 on the side of the substrate 12 adjacent to the first tool 32 of the clamping device 30.

In accordance with an embodiment, the step of exerting 140 mechanical pressure F_{P} between the first and second tools 32, 34 of the clamping device 30 may be performed at a contact pressure (between the first and second tools 32, 34) of greater than 10 N/cm² or in a range between 10 N/cm² and 600 N/cm².

In accordance with an embodiment, the first or second tool 32, 34 or both tools 32, 34 of the clamping device 30 may be configured to heat the (clamped) stack arrangement 10 to the (increased) process temperature T_{P}. This process may also be referred to as tempering. In the context of the present description, tempering (exerting the process temperature) is understood to mean temperature treatment, for example time-controlled, homogeneous heating of the stack arrangement, this temperature treatment being exerted, for example, while exerting the planar-acting mechanical pressure F_{P} between the first and second tools 32, 34 of the clamping device 30.

Step 140 of exerting a process temperature T_{P} on the stack arrangement 10 may, for example, be performed with a predetermined temperature profile (or temperature ramp). Exerting 140 the process temperature T_{P} (peak temperature) on the stack arrangement 10 may, for example, (depending on the material of the metal film 14) take place for 1 to 30 (e.g. 3 to 15 or 3 to 5) seconds.

Heating the stack arrangement 10 and exerting 140 the process temperature T_{P} (peak temperature) on the stack arrangement 10 may, for example, take place independently of alloying, provided that this has already been presented. The production of an AlCu melt may take place during heating and does not lead to a significant extension of the process. The extension (due to the alloying) may be in a range from 15 to 20 seconds.

As shown as an example in step 120 of FIG. 2A, the stack arrangement 10 has the compressible surface sealing element 16 (high-temperature seal) in the vertical direction (from top to bottom in FIG. 2A), the metal film 14 having the aluminum material (=also an aluminum material alloy) and the substrate 12 provided with the channel structure or channel structures 12-1, e.g. a perforated glass-quartz, sapphire-ceramic or semiconductor substrate (wafer). In the embodiment of the manufacturing method 100 shown in FIG. 2A, the first tool 32 is configured, for example, as a press punch and the second tool 34 of the clamping device 30 is configured as a (e.g. coated) counter substrate, wherein the second tool 34 is also effective as a flow stop for the liquefied material 14-1 of the metal film 14 during the filling process.

The material of the compressible surface sealing element 16 also prevents the liquid aluminum 14-1 from coming into contact with the pressure or press punch 32. In addition, the liquefied aluminum 14-1 does not adhere to the material of the compressible surface sealing element (the high-temperature surface seal) 16. Typical suitable materials for the compressible surface sealing element are, for example, graphite or materials such as boron nitride, etc.

With regard to the process flow 100 shown in FIG. 2A, it is further pointed out that the stack arrangement 10 may also have an inverted (reversed) order between the first and second tools 32, 34 of the clamping device 30, without (significantly) changing or impairing the process result, since gravity effects (generally speaking) have no influence on the filling process.

By exerting the planar-acting mechanical process pressure F_{P} and the increased process temperature T_{P} (tempering process) with liquefying (melting) the material of the metal film 14, which comprises an aluminum material, pressure filling of the channel structure(s) 12-1 of the substrate 12 takes place. In this case, the metal film 14 is surrounded or enclosed by the surface sealing element 16 up to the substrate 12 (also laterally) by the compression (planar-acting exertion of mechanical pressure) of the compressible surface sealing element 16. Due to the flow-stop effect of the counter substrate or the surface 34-1 of the counter substrate 34, the filling process in step 140 takes place up to the surface 34-1 of the second tool 34 of the clamping device 30 acting as a counter substrate.

In accordance with an embodiment, a main surface region 34-1 of the second tool 34 (of the counter substrate) facing the substrate 12 may have a surface roughness with a center roughness value Rₐ or an average roughness depth R_{Z} between 0.5 μm and 10 μm or of about 3 μm. This surface quality (the roughness) of the main surface region 34-1 of the second tool 34 facing the substrate 12 prevents the molten metal (molten aluminum) from adhering to this main surface region 34-1 of the second tool 34 during the pressure filling process and also prevents the hot substrate 12 (e.g. the glass substrate), which is at the process temperature T_{P}, from adhering to this main surface region 34-1 of the second tool 34.

In accordance with an embodiment, the main surface region 34-1 of the second tool 34 facing the substrate 12 may have a coating 36 to provide this surface roughness of the main surface region 34-1 of the second tool 34 facing the substrate 12. Thus, the surface roughness of the main surface region 34-1 of the second tool 34 facing the substrate 12 may be obtained, for example, by means of the coating 36, wherein the coating 36 may comprise or consist of a boron nitride material. The boron nitride (BN) does not react with the liquefied material (aluminum material) 14-1 of the metal film 14, as boron nitride is oxidation-resistant up to about 800° C. and does not have/enter into a reaction with glass or metal. In addition, BN does not adhere to glass, nor does the hot glass mass adhere to the BN

Furthermore, the boron nitride material may provide the desired surface roughness of the second tool 34, which may further allow air/gas to escape laterally from the channel structures 12-1 of the substrate 12 during the filling process, while the surface quality has or provides the desired flow stop effect for the molten metal 14-1 on the surface 34-1 of the counter substrate 34 (second tool).

As further exemplified in FIG. 2A of the manufacturing method 100, the first tool 32 (the press punch) may further comprise a non-stick coating 38 on its main surface region 32-1 (which faces the substrate 12), which allows for simplified detachment (removal) of the first tool 32 from the stack arrangement 10, i.e., from the compressible face seal element 16, after the filling and cooling operation 140, 160 of the method 100. For example, the non-stick coating 36 may be arranged on (or form) the main surface region 32-1 of the first tool 32 facing the stack arrangement 10.

Thus, in accordance with an embodiment, the coating 36 of the second tool 34 may comprise a boron nitride material, wherein the surface roughness of the main surface region of the second tool 34 adjacent to the substrate 12 is selected to be effective as a flow stop for the molten metal, and to allow lateral escape of a gas present in the channel structure 12-1 of the substrate 12. Thus, the flow front of the molten material 14-1 of the metal film 14 may impinge on a plate 34 (second tool 34) located below the substrate 12 and having the rough boron nitride coating. The flow front pushes the gas in the channel out downwards and stops planar on the substrate 12. The gap configured by the roughness of the coating is so narrow that the flow front may not move laterally between the substrate 12 (e.g. glass substrate) and the second tool (counter-substrate plate) 34. With this procedure, a protective gas atmosphere is helpful/possible, but not absolutely necessary. This may provide sufficient control of the flow front.

In accordance with an embodiment, the substrate 12 may, for example, comprise a dielectric material, such as glass, quartz, sapphire, ceramic, etc., or a semiconductor material, such as silicon (poly-silicon). When using silicon (poly-silicon) for the substrate 12, it may, for example, be entailed to provide an additional barrier and insulation layer, e.g. made of SiO₂, in order to prevent a possible reaction of the hot liquid Al material with the silicon.

Step 160 of cooling the stack arrangement 10 may, for example, be carried out with a predetermined temperature profile (or temperature ramp, as in the step of exerting the process temperature), for example to ensure that the cooling of the elements and structures involved is carried out as gently as possible on the material, due to different thermal expansion coefficients.

The cooling process 160 may, for example, take place at an (average) temperature change (cooling) of 20 to 500 K (or 30 to 400 K or 300 to 400 K) per minute (until a normal temperature is reached (e.g. removal temperature of the filled substrate 12, e.g. in a range between the ambient temperature and about 200° C.). The time entailed for the cooling process may depend, for example, on the structure of the clamping device 30 and, for example, the punch unit 32.

After step 160 of cooling the stack arrangement 10 and the clamping device 30, the stack arrangement 10 may be removed from the clamping device 30 after the planar-acting mechanical process pressure F_{P} has been released, whereupon the surface sealing element 16 may also be removed from the substrate 12. After removal of the substrate (e.g. glass substrate) 12, for example equipped with the aluminum feedthroughs (e.g. aluminum TGVs) 12-2, and the relaxed sealing (surface sealing element) 16, the substrate 12 provided with the electrically conductive channel structure(s) 12-2 may then, for example, be fed to further processing or further processing steps.

Thus, the method 100 may further (optionally) remove excess metallic filling material 14-2 from one side of a main surface region or from both sides of opposing main surface regions of the substrate 12, for example using a chemical mechanical polishing (CMP) process.

Furthermore, in the method 100, metallization may (optionally) be performed on one or both sides on the substrate 12 using a thin-film deposition process to obtain, a metallization structure electrically connected to the conductive channel structure 12-2 on one or both main surface regions of the substrate 12 configured with the conductive channel structure 12-2, for example, via a lithographic patterning process and a subsequent etching step.

The inventive method 100 for manufacturing an electrically conductive channel structure 12-2 in the substrate 12 may thus be used to obtain, for example, an arrangement, such as an interposer 50, comprising channel structures 12-2 completely filled with metal in the substrate 12 (e.g. a flat substrate), wherein, for example, a chemical bonding zone (interface) of the metal filling 14-1 of the channel structures 12-2 to the channel walls is obtained without requiring or using, for example, a metallic thin film adhesion promoter coating in the method.

With regard to the stack arrangement 10 shown in FIG. 2A in the description of the manufacturing method 100, it is pointed out that a plurality of such stack arrangements 10 may also be arranged between the first and second tools 32, 34 of the clamping device 30 in order to carry out the manufacturing method 100 of FIG. 2A. It is only to be noted that either the compressible surface sealing element 16 used or a further intermediate layer may be used as the respective counter substrate 34 for providing the flow-stop effect.

In accordance with an embodiment, the channel structure 12-1 may be configured as at least one through-hole structure, at least one blind-hole structure or at least one 3D structure in the substrate 12 so that, after performing the method 100, an electrically conductive channel structure 12-2 in the substrate 12 is obtained in the form of a conductive through-hole structure, at least one conductive blind-hole structure or at least one conductive 3D structure in the substrate.

In accordance with an embodiment, the (increased) process temperature T_{P} may be set to a value of at least 5 K, 10 K or 20 K above the melting temperature of the metal film 14 comprising the aluminum material. The process temperature T_{P} is thus selected to ensure safe melting of the material of the metal film 14 with the lowest possible thermal stress on the elements and structures involved. For this purpose, the first or second tool 32, 34 or both tools 32, 34 may be configured to heat the stack arrangement 10 to the desired process temperature T_{P}, i.e. to carry out the tempering process at the desired process temperature T_{P}.

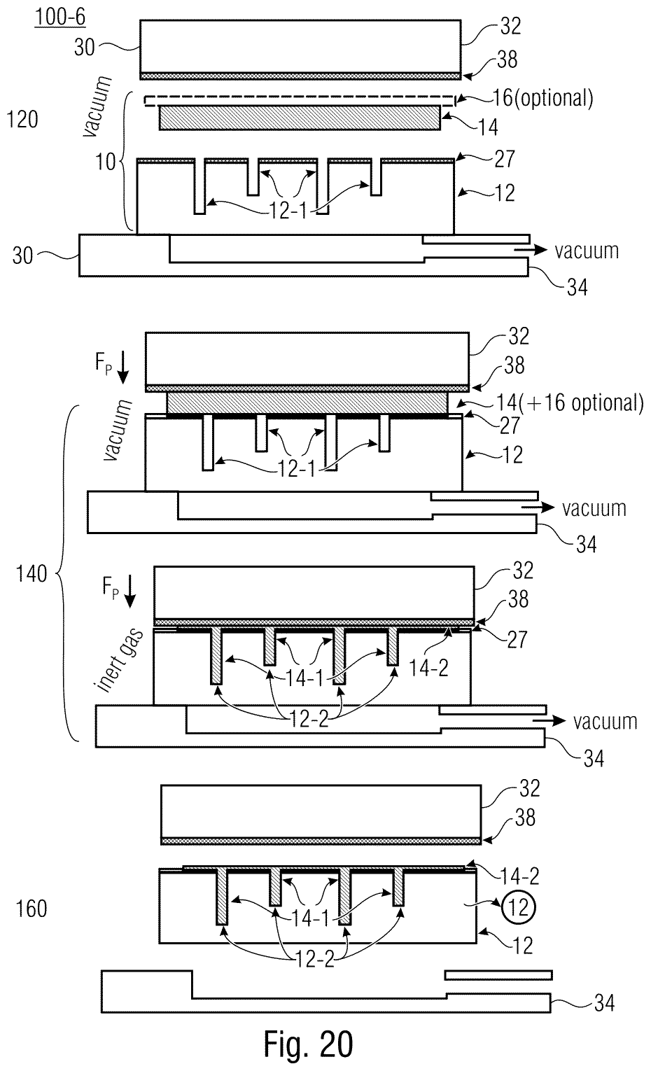

In the melt filling of the channel structures 12-1 of the substrate 12 defined according to the method 100, the process temperature is thus at least 5 K, 10 K or 20 K more than the melting temperature of the metal of the metal film 14 selected for the filling. The process temperature is, for example, limited upwards by the softening temperature of the substrate material. If, for example, glass is used as the substrate material, its viscosity decreases with increasing temperature (e.g. continuously), wherein glass is an amorphous inorganic material. By using a supporting substrate material 13 (see e.g. FIG. 20) having a high melting temperature or softening temperature, e.g. silicon, even low-melting glass substrates 12 may be filled with aluminum or an aluminum alloy without bending or changing the structure of such a glass substrate 12.

In accordance with an embodiment, the metal film 14 may have the aluminum material as its main component, e.g. having a proportion of ≥80%, 90% or 95%, or even pure aluminum (=proportion 100%) for a resulting melting point of at least 420° C. or 520° C. or between 420° C. (or 520° C.) and 850° C. This means that the material of the metal film is a hard soldering material, as the solder temperature is by definition above 420° C. or even above 520° C.

By means of the melting temperature and the “over” temperature above it (process temperature=melting temperature+May 10, 2020 K), the wetting capacity of a pure aluminum melt (without oxygen in the environment) in the hole structures 12-1 can be improved by reducing the surface tension of the molten metal 14-1 by approx. 5% (e.g. filling temperature approx. 830° C.), while the density of the melt 14-1 and the viscosity are little affected by this. In the case of aluminum-copper alloys for the metal film 14, this effect is pronounced and depends on the copper content. Since higher alloying proportions (of copper) may increase the strength and generally also result in significantly increased contact resistances, the metal material of the metal film has the aluminum material as its main component, e.g. at least 80%, 90%, 95% or 99%. While the density, surface tension and viscosity of pure aluminum depend little on the temperature, this has a significant effect on the viscosity in aluminum-copper alloys.

The metal film 14 comprising the aluminum material (as the main component) may have a single-layer or multi-layer film structure. Thus, the metal film 14 may have a single-layer aluminum material, as a two-layer composite an aluminum layer and a copper layer (or film), as a three-layer composite an aluminum layer, a copper layer and again an aluminum layer, etc., insofar as the aluminum material is the main component of the multilayer film structure (and rests on the substrate 12).

The glass materials used for the substrate (glass substrate) 12 may be, for example, a Borofloat® glass (Borofloat 33 from Schott) or another glass, such as Schott AF32, Corning Eagle XG, Hoya SD2.

In accordance with an embodiment, the surface sealing element 16 may cover the metal film 14 and have a lateral projection (over the metal film 14) in order to enclose the metal film 14 up to the substrate 12 (hermetically sealed) when the mechanical process pressure F_{P} and the process temperature T_{P} are exerted. In accordance with an embodiment, the compressible surface sealing element 16 may be configured as a reusable high-temperature seal.

In accordance with a further embodiment, the surface sealing element 16 may comprise or consist of a graphite film having a thickness in a range from 0.3 mm to 1 mm or of about 0.5 mm.

In addition to graphite, other materials which do not adhere to the liquid Al material, such as other carbons, SiC or BN, can be considered as materials for the compressible surface sealing element 16. For example, fabrics made of/with graphite, SiC and/or BN fibers (individually or in a combination) may also be used.

Due to the compressible high-temperature surface sealing (e.g. a graphite film) 16 with the (lateral) overlap over the edge of the applied metal film (e.g. aluminum or aluminum alloy film), the molten metal (the molten material 14-1 of the metal film 14) may be held above the substrate region (having the channel structures 12-1) of the substrate 12 to be filled and lateral squeezing (escape) under pressurization F_{P} may be avoided during the step of exerting a planar-acting mechanical process pressure F_{P} and the process temperature T_{P}. By using the compressible surface sealing element 16, very high yields may be achieved in the manufacturing method 100.

The lateral protrusion of the surface sealing over the metal film may, for example, depend on the thickness of the metal film and/or the thickness of the surface seal. For an Al film of thickness H, a seal 16 of thickness D may have an overlap (lateral projection) or a width of the externally sealing area W in the following ratio: W>50×H/D mm, or 100×H/D mm>W>50×H/D mm.

In the context of the present description of the method 100, filling or filling process refers to introducing molten metal 14-1 to completely or even partially fill cavities or channel structures 12-1 in a substrate 12, for example a ceramic, glass or silicon substrate. Filling may also be understood as an inner wall lining of cavities or channel structures 12-1 in the substrate 12 with a metal coating or also a filling limited in the depth of the channel structure 12-1.

The substrate 12 is understood to be, for example, a material body having two opposing parallel main surface regions (sides), wherein this is independent of the width to height ratio. The opposing sides of the substrate 12 may, but need not, be arranged parallel to each other or may also be arranged to be non-parallel to each other in some regions.

In the context of the present description, the term channel, channel structure or cavity 12-1 refers to a recess having at least one open side (opening) to an outer side of the substrate 12, this being independent of the geometric shape of the recess 12-1, for example in the form of a lateral slot, a pocket, a blind hole or a perforation, or a channel in any geometric design having at least one opening to a substrate surface.

Although the present description often refers to an aluminum filling (based on the metal film comprising an aluminum material), the inventive method may also be applied to filling with ultra-pure aluminum or aluminum alloys. For example, alloys having a lower melting point in relation to ultra-pure aluminum may be used, wherein one or more alloying elements from the fields of copper, silicon, germanium and/or magnesium may be used. Furthermore, alloys or Al alloys having improved electrical properties, e.g. against electromigration, such as Al—Si or AlCu (each containing a few %, e.g. 1 to 5%) may be used. This list of alloying elements is intended to be only exemplary and not exhaustive.

It is further noted that the term film in “metal film, aluminum film, aluminum alloy film” 14 in the context of the present description includes the use of stacked individual films but also thin metal sheets or roll-plated sheets, e.g. of aluminum copper, from which alloys are formed, for example, during the filling process and which (at least partially) fill the channel structures or perforations 12-1 of the substrate 12.

Typical thicknesses of metal films and metal sheets may range from 20 μm to 1000 μm or between 20 μm and 50 μm and around (typically) 30 μm.

In accordance with an embodiment, the metal film comprises the aluminum material as a main component having a volume proportion of >60%, >80% or also >90%. Furthermore, by the inventive manufacturing method 100, the electrically conductive channel structures 12-2 in the substrate 12 may fill a metal filling 14-1 to a degree of 90% or also between 95% and 98% and up to 100%, i.e. the channel structure 12-2 is filled completely (i.e. at least to 90% or 98%), free of pores or inclusions.

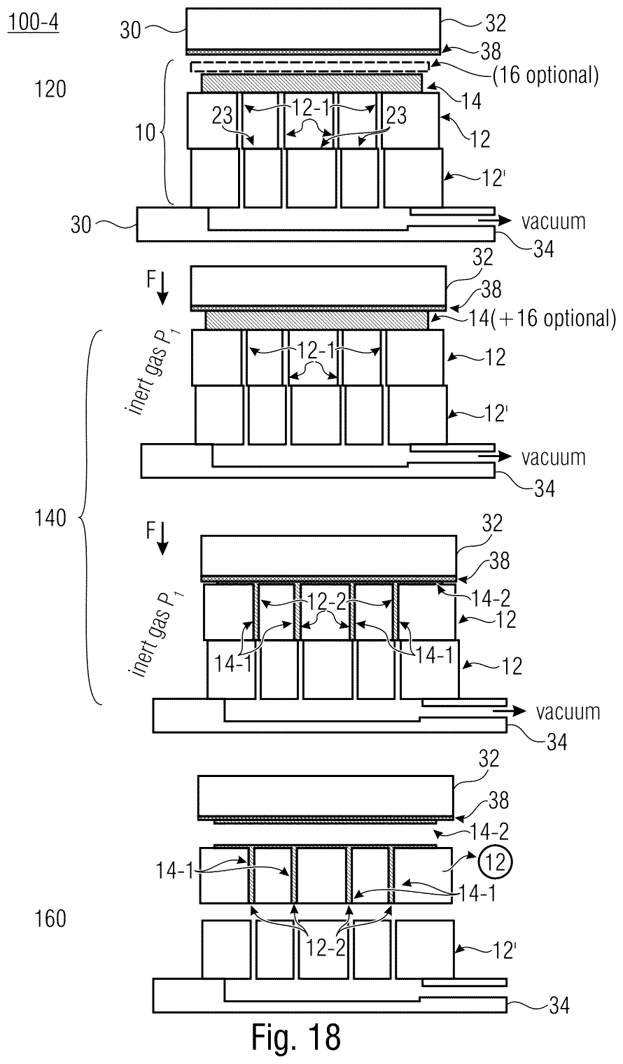

In accordance with an embodiment, for example, temperature-resistant temporary carrier substrates 13 (see e.g. FIG. 18), such as silicon wafers, may be used for the purely aluminum melt filling of channel structures 12-1 in low-melting glass substrates 12, e.g. Schott BF33. These carrier substrates 13 may in turn be equipped with suction hole channels which are aligned with the bores in the glass substrate. The alignment may be realized by placing, by passive alignment aids (e.g. pins, balls) or by anodic bonding carried out before. The carrier substrate may be discarded after filling or may be configured with a non-stick coating for reuse.

In accordance with an embodiment, filling may also be done with a low melting point aluminum-copper alloy in the manufacturing method 100. This alloy may be introduced as a pre-alloyed film or may be formed in situ from (at least) an aluminum film and (at least) a copper film by forming an aluminum-copper eutectic during the heating phase of the pressure punch 32. The process temperature may be lowered by about 100 K (compared to pure aluminum), which enables the filling of low-melting substrates 12, e.g. glass substrates, without deformation.

For example, the method 100 may be performed in a process chamber having a predetermined (e.g., inert) process atmosphere and a predetermined atmospheric process pressure.

FIG. 2B shows an exemplary principle flow diagram of the inventive method 100 for manufacturing an electrically conductive channel structure 12-2 in a substrate 12, wherein, for example, an enclosing ring seal is used as a compressible sealing element 16.

In the further embodiment of the flow diagram of the manufacturing method 100 shown in FIG. 2B below, the method steps shown in FIGS. 1 and 2A are again performed, with the additions and changes (differences) compared to the manufacturing method 100 described above being shown below. Except for the shape of the compressible sealing element 16 as an enclosing ring seal, the above explanations of the manufacturing method 100 in FIGS. 1 and 2A are equally applicable to the embodiment of the manufacturing method 100 of FIG. 2B. This also applies (in particular) to the materials of the compressible sealing element 16, the process flow, the process parameters, all other elements described and their properties, etc.

In accordance with an embodiment of FIG. 2B, the compressible sealing element 16 has, for example, an enclosing ring seal. Furthermore, the compressible sealing element 16 may be configured for high-temperature applications at the process temperature (as a compressible high-temperature sealing element).

FIG. 2B thus shows a possible implementation of the various method steps of the schematic flow chart of the manufacturing method 100 shown with reference to FIG. 1. The arrangement obtained in the manufacturing method 100, i.e. a substrate having electrically conductive channel structures or vias, may then be used, for example, as a so-called interposer arrangement 50 for electronic components, such as a rerouting interposer, as a conductive via, as a (passive) electrical component or for heat dissipation, etc.

Referring to the method 100 of FIG. 2B, in step 120, a stack arrangement 10 is provided in a clamping device 30 (clamping arrangement), wherein the stack arrangement 10 comprises a substrate 12 provided with a channel structure 12-1, a metal film 14 comprising an aluminum material or an aluminum material alloy on the substrate 12, and a compressible ring sealing member 16 surrounding the edge region of the metal film and laterally enclosing the metal film under the application of pressure.

In accordance with an embodiment of the manufacturing method 100 shown in FIG. 2B, the clamping device 30 may have a first and a second tool 32, 34, wherein the stack arrangement 10 is arranged or clamped (flush) between the first and second tools 32, 34 of the stack arrangement 30.

In (subsequent) step 140, a planar-acting mechanical process pressure F_{P} and a process temperature T_{P} are exerted on the stack arrangement 10 with (by means of) the clamping device 30 in order to melt (liquefy) the metal film 14 comprising the aluminum material at the process temperature T_{P} and to introduce it into the channel structure(s) 12-1 as metallic filling material 14-1 by means of the planar-acting mechanical process pressure F_{P}.

In step 140, for example, the liquefied material 14-1 of the metal film 14 is enclosed between a first tool (e.g. press punch) of the clamping device and the substrate provided with the channel structures, wherein a compressible ring sealing element (=an enclosing ring seal) surrounds (encloses) the edge region of the metal film so that the ring sealing element surrounds (hermetically or tightly encloses) the metal film laterally (between the substrate and the first tool) when pressure is exerted. This may prevent lateral leakage (escape) of the liquefied/molten material of the metal film through the surrounding ring sealing element.

The ring sealing element 16 may have an inner circumferential shape (ring shape) which is adapted, for example, to the outer circumferential shape of the metal film 14. The inner circumferential shape of the ring sealing element 16 may, for example, have a configuration that is flush with or conforms to the outer region (to the outer circumferential shape) of the metal film 14.

In a subsequent step 160, the stack arrangement 10 is cooled to re-solidify (solidify) the introduced metallic (molten) filling material 14-1 to obtain the electrically conductive channel structure(s) 12-2 filled with the (solidified) metallic filling material 14-1.

Thus, in the exemplary manufacturing method 100 illustrated in FIG. 2B, an aluminum pressure melt filling of the channel structures 12-1 is performed in the substrate 12. Here, the (second) tool 34 of the clamping device 30 arranged on the substrate 12 serves, for example, as a counter substrate to obtain a flow stop (or a flow stop function) during the melt filling process, wherein the compressible high-temperature seal 16 is provided as a lateral boundary or enclosure to cause lateral leakage or escape of the liquefied (molten) material 14-1 of the metal film 14 on the side of the substrate 12 adjacent to the first tool 32 of the clamping device 30.

In accordance with an embodiment, the step of exerting 140 mechanical pressure F_{P} between the first and second tools 32, 34 of the clamping device 30 may be performed having a contact pressure (between the first and second tools 32, 34) of greater than 10 N/cm² or in a range between 10 N/cm² and 600 N/cm².

In accordance with an embodiment, the first or second tool 32, 34 or both tools 32, 34 of the clamping device 30 may be configured to heat the (clamped) stack arrangement 10 to the (increased) process temperature T_{P}. This process may also be referred to as tempering. In the context of the present description, tempering (exerting the process temperature) is understood to mean temperature treatment, for example time-controlled, homogeneous heating of the stack arrangement, this temperature treatment being exerted, for example, while exerting the planar-acting mechanical pressure F_{P} between the first and second tools 32, 34 of the clamping device 30.

Step 140 of exerting a process temperature T_{P} on the stack arrangement 10 may, for example, be performed with a predetermined temperature profile (or temperature ramp). Exerting 140 the process temperature T_{P} (peak temperature) on the stack arrangement 10 may, for example, (depending on the material of the metal film 14) take place for 1 to 30 (e.g. 3 to 15 or 3 to 5) seconds.

Heating the stack arrangement 10 and exerting 140 the process temperature T_{P} (peak temperature) on the stack arrangement 10 may, for example, take place independently of alloying, provided that this has already been presented. The production of an AlCu melt may take place during heating and does not result in a significant extension of the process. The extension may be in the range of 15 to 20 seconds.

As shown as an example in step 120 of FIG. 2B, the stack arrangement 10 has, in the vertical direction (from top to bottom in FIG. 2B), the metal film 14 with the laterally surrounding ring sealing element 16 (high-temperature seal) and the substrate 12 provided with the channel structure or channel structures 12-1, for example a perforated glass-quartz, sapphire-ceramic or semiconductor substrate (wafer). In an embodiment of the manufacturing method 100 shown in FIG. 2B, the first tool 32 is configured, for example, as a press punch and the second tool 34 of the clamping device 30 is configured as a (e.g. coated) counter substrate, wherein the second tool 34 is also effective as a flow stop for the liquefied material 14-1 of the metal film 14 during the filling process.

With regard to the process flow 100 shown in FIG. 2B, it is further pointed out that the stack arrangement 10 may also have an inverted (reversed) order between the first and second tools 32, 34 of the clamping device 30 without the process result being (significantly) changed or impaired, since gravity effects have (essentially) no influence on the filling process.

By exerting the planar-acting mechanical process pressure F_{P} and the increased process temperature T_{P} (tempering process) with the effect of liquefying (melting) the material of the metal film 14, which comprises an aluminum material, pressure filling of the channel structure(s) 12-1 of the substrate 12 takes place. In this case, the metal film 14 is laterally surrounded or enclosed by the directional sealing element 16 during compression (during the planar-acting exertion of mechanical pressure) of the compressible ring sealing element 16. Due to the flow stop effect of the counter substrate or the surface 34-1 of the counter substrate 34, the filling process in step 140 takes place up to the surface 34-1 of the second tool 34 of the clamping device 30 acting as a counter substrate.

In accordance with an embodiment, a main surface region 34-1 of the second tool 34 (of the counter substrate) facing the substrate 12 may have a surface roughness having a center roughness value Rₐ or an average roughness depth R_{Z} between 0.5 μm and 10 μm or of about 3 μm. This surface quality (the roughness) of the main surface region 34-1 of the second tool 34 facing the substrate 12 prevents the molten metal (molten aluminum) from adhering to this main surface region 34-1 of the second tool 34 during the pressure filling process and also prevents the hot substrate 12 (e.g. the glass substrate), which is at the process temperature T_{P}, from adhering to this main surface region 34-1 of the second tool 34.

In accordance with an embodiment, the main surface region 34-1 of the second tool 34 facing the substrate 12 may have a coating 36 to provide this surface roughness of the main surface region 34-1 of the second tool 34 facing the substrate 12. Thus, the surface roughness of the main surface region 34-1 of the second tool 34 facing the substrate 12 may be obtained, for example, by means of the coating 36, wherein the coating 36 may comprise or consist of a boron nitride material. The boron nitride (BN) does not react with the liquefied material (aluminum material) 14-1 of the metal film 14, as boron nitride is oxidation-resistant up to about 800° C. and does not have/enter into a reaction with glass or metal. In addition, BN does not adhere to glass, nor does the hot glass mass adhere to the BN.

Furthermore, the boron nitride material may provide the desired surface roughness of the second tool 34, which may further allow air/gas to escape laterally from the channel structures 12-1 of the substrate 12 during the filling process, while the surface quality has or provides the desired flow stop effect for the molten metal 14-1 on the surface 34-1 of the counter substrate 34 (second tool).

As further exemplified in FIG. 2B of the manufacturing method 100, the first tool 32 (the press punch) may further comprise a non-stick coating 38 on its main surface region 32-1 (which faces the substrate 12), which allows for simplified detachment (removal) of the first tool 32 from the stack arrangement 10, i.e., from the compressible sealing member 16, after the filling and cooling operation 140, 160 of the method 100. For example, the non-stick coating 36 may be arranged on (or form) the main surface region 32-1 of the first tool 32 facing the stack arrangement 10.

Thus, in accordance with an embodiment, the coating 36 of the second tool 34 may comprise a boron nitride material, wherein the surface roughness of the main surface region of the second tool 34 adjacent to the substrate 12 is selected to be effective as a flow stop for the molten metal, and to allow lateral escape of a gas present in the channel structure 12-1 of the substrate 12. Thus, the flow front of the molten material 14-1 of the metal film 14 may impinge on a plate 34 (second tool 34) located below the substrate 12 and having the rough boron nitride coating. The flow front pushes the gas in the channel out downwards and stops planar on the substrate 12. The gap configured by the roughness of the coating is so narrow that the flow front may not move laterally between the substrate 12 (e.g. glass substrate) and the second tool (counter-substrate plate) 34. With this procedure, a protective gas atmosphere is helpful/possible, but not absolutely necessary. This may provide sufficient control of the flow front.

In accordance with an embodiment, the substrate 12 may, for example, comprise a dielectric material, such as glass, quartz, sapphire, ceramic, etc., or a semiconductor material, such as silicon (poly-silicon). If silicon (poly-silicon) is used for the substrate 12, it may, for example, be entailed to provide an additional barrier and insulation layer, e.g. of SiO₂, in order to prevent a possible reaction of the hot liquid Al material with the silicon.

Step 160 of cooling the stack arrangement 10 may, for example, be carried out with a predetermined temperature profile (or temperature ramp, as in the step of exerting the process temperature), for example to ensure that cooling of the elements and structures involved is carried out as gently as possible on the material, due to different thermal expansion coefficients.

The cooling process 160 may, for example, take place at an (average) temperature change (cooling) of 20 to 500 K (or 30 to 400 K or 300 to 400 K) per minute (until a normal temperature is reached (e.g. removal temperature of the filled substrate 12, e.g. in a range between ambient temperature and about 200° C.). The time entailed for the cooling process may depend, for example, on the structure of the clamping device 30 and, for example, the punch unit 32.

After step 160 of cooling the stack arrangement 10 and the clamping device 30, the stack arrangement 10 may be removed from the clamping device 30 after the planar-acting mechanical process pressure F_{P} has been released, whereupon the ring seal element 16 may also be removed from the substrate 12. After removal of the substrate (e.g. glass substrate) 12, for example equipped with the aluminum feedthroughs (e.g. aluminum TGVs) 12-2, and the relaxed sealing (ring sealing element) 16, the substrate 12 provided with the electrically conductive channel structure(s) 12-2 may then, for example, be fed to further processing or further processing steps.

Thus, the method 100 may further (optionally) remove excess metallic filling material 14-2 from one side of a main surface region or from both sides of opposing main surface regions of the substrate 12, for example using a chemical mechanical polishing (CMP) process.

Further, in the method 100, metallization may (optionally) be performed on one or both sides of the substrate 12 using a thin-film deposition process to obtain, for example, a metallization structure electrically connected to the conductive channel structure 12-2 on one or both main surface regions of the substrate 12 configured with the conductive channel structure 12-2, via a lithographic patterning process and a subsequent etching step.

The inventive method 100 for manufacturing an electrically conductive channel structure 12-2 in the substrate 12 may thus be used to obtain, for example, an arrangement, such as an interposer 50, comprising channel structures 12-2 completely filled with metal in the substrate 12 (e.g. a flat substrate), wherein, for example, a chemical bonding zone (interface) of the metal filling 14-1 of the channel structures 12-2 to the channel walls is obtained without requiring or using, for example, a metallic thin-film adhesion promoter coating in the method.

With regard to the stack arrangement 10 shown in FIG. 2B in the description of the manufacturing method 100, it is pointed out that a plurality of such stack arrangements 10 may also be arranged between the first and second tools 32, 34 of the clamping device 30 in order to carry out the manufacturing method 100 of FIG. 2B. It is only to be noted that a further intermediate layer may be used as a respective counter substrate 34 for providing the flow stop effect.

In accordance with an embodiment, the channel structure 12-1 may be configured as at least one through-hole structure, at least one blind-hole structure or at least one 3D structure in the substrate 12 so that after performing the method 100, an electrically conductive channel structure 12-2 in the substrate 12 is obtained in the form of a conductive through-hole structure, at least one conductive blind-hole structure or at least one conductive 3D structure in the substrate.

In accordance with an embodiment, the (increased) process temperature T_{P} may be set to a value of at least 5 K, 10 K or 20 K above the melting temperature of the metal film 14 comprising the aluminum material. The process temperature T_{P} is thus selected to ensure safe melting of the material of the metal film 14 with the lowest possible thermal stress on the elements and structures involved. For this purpose, the first or second tool 32, 34 or both tools 32, 34 may be configured to heat the stack arrangement 10 to the desired process temperature T_{P}, i.e. to carry out the tempering process at the desired process temperature T_{P}.

In the melt filling of the channel structures 12-1 of the substrate 12 defined according to the method 100, the process temperature is thus at least 5 K, 10 K or 20 K more than the melting temperature of the metal film 14 selected for the filling. The process temperature is, for example, limited upwards by the softening temperature of the substrate material. If, for example, glass is used as the substrate material, its viscosity decreases with increasing temperature (e.g. continuously), wherein glass is an amorphous inorganic material. By using a supporting substrate material 13 (see e.g. FIG. 20) having a high melting temperature or softening temperature, e.g. silicon, even low-melting glass substrates 12 may be filled with aluminum or an aluminum alloy without bending or changing the structure of such a glass substrate 12.

In accordance with an embodiment, the metal film 14 may have the aluminum material as its main component, e.g. having a proportion of ≥80%, 90% or 95%, or even pure aluminum (=proportion 100%) for a resulting melting point of at least 420° C. or 520° C. or between 420° C. (or 520° C.) and 850° C. This means that the material of the metal film is a hard soldering material, as the solder temperature is by definition above 420° C. or even above 520° C.

By means of the melting temperature and the “over” temperature above it (process temperature=melting temperature+May 10, 2020 K), the wetting capacity of a pure aluminum melt (without oxygen in the environment) in the hole structures 12-1 may be improved by reducing the surface tension of the molten metal 14-1 by approx. 5% (e.g. filling temperature approx. 830° C.), while the density of the melt 14-1 and the viscosity are little affected by this. In the case of aluminum-copper alloys for the metal film 14, this effect is pronounced and depends on the copper content. Since higher alloying proportions (of copper) may increase the rigidity and generally also result in significantly increased contact resistances, the metal material of the metal film has the aluminum material as its main component, e.g. at least 80%, 90%, 95% or 99%. While the density, surface tension and viscosity of pure aluminum depend little on the temperature, this has a significant effect on the viscosity in aluminum-copper alloys.

The metal film 14 comprising the aluminum material (as the main component) may have a single-layer or multi-layer film structure. Thus, the metal film 14 may have a single-layer aluminum material, as a two-layer composite an aluminum layer and a copper layer (or film), as a three-layer composite an aluminum layer, a copper layer and again an aluminum layer, etc., insofar as the aluminum material is the main component of the multilayer film structure (and rests on the substrate 12).

The glass materials used for the substrate (glass substrate) 12 may be, for example, a Borofloat® glass (Borofloat 33 from Schott) or another glass, such as Schott AF32, Corning Eagle XG, Hoya SD2.

In accordance with an embodiment, the ring sealing element 16 may laterally enclose (surround) the metal film 14 or the edge region in order to laterally enclose the metal film 14 when the mechanical process pressure F_{P} and the process temperature T_{P} are exerted and to prevent lateral leakage (escape) of the liquefied/molten material of the metal film through the surrounding ring sealing element. In accordance with an embodiment, the compressible sealing element 16 may be configured as a reusable high-temperature seal.

In accordance with a further embodiment, the ring sealing element 16 may comprise or consist of a structured film, for example a structured graphite film, having a thickness (vertical height) in a range from 0.3 mm to 1 mm or of about 0.5 mm. The (lateral) width B of the ring sealing element 16 may be in a range from 0.5 mm to 20 mm or from 2 to 5 mm.

In addition to graphite, other materials which do not adhere to the liquid Al material, such as other carbons, SiC or BN, can be considered as materials for the compressible surface sealing element 16. For example, fabrics made of/with graphite, SiC and/or BN fibers (individually or in a combination) may also be used.

Due to the compressible high-temperature ring sealing (e.g. a structured graphite film) 16 laterally around the applied metal film (e.g. aluminum or aluminum alloy film), the molten metal (the molten material 14-1 of the metal film 14) can be held above the substrate area to be filled (having the channel structures 12-1) of the substrate 12 and lateral squeezing out (escape) under pressurization F_{P} can be avoided during the step of exerting a planar-acting mechanical process pressure F_{P} and the process temperature T_{P}. By using the compressible ring sealing element 16, very high yields may be achieved in the manufacturing process 100.

In the context of the present description of the method 100, filling or filling process refers to introducing molten metal 14-1 to completely or even partially fill cavities or channel structures 12-1 in a substrate 12, for example a ceramic, glass or silicon substrate. Filling may also be understood as an inner wall lining of cavities or channel structures 12-1 in the substrate 12 having a metal coating or also a filling limited in the depth of the channel structure 12-1.

The substrate 12 is understood to be, for example, a material body which has two opposing parallel main surface regions (sides), wherein this is independent of the width to height ratio. The opposing sides of the substrate 12 may, but need not, be arranged parallel to each other or may also be arranged non-parallel to each other in some areas.

In the context of the present description, the term channel, channel structure or cavity 12-1 refers to a recess having at least one open side (opening) to an outer side of the substrate 12, this being independent of the geometric shape of the recess 12-1, for example in the form of a lateral slot, a pocket, a blind hole or a perforation, or a channel in any geometric design having at least one opening to a substrate surface.

Although the present description often refers to an aluminum filling (based on the metal film comprising an aluminum material), the inventive method may also be applied to filling with ultra-pure aluminum or aluminum alloys. For example, alloys having a lower melting point in relation to ultra-pure aluminum may be used, wherein one or more alloying elements from the fields of copper, silicon, germanium and/or magnesium may be used. Furthermore, alloys or Al alloys having improved electrical properties, e.g. against electromigration, such as Al—Si or AlCu (each containing a few %, e.g. 1 to 5%) may be used. This list of alloying elements is only exemplary and not exhaustive.

It is further noted that the term film in “metal film, aluminum film, aluminum alloy film” 14 in the context of the present description includes the use of stacked individual films but also thin metal sheets or roll-plated sheets, for example of aluminum-copper, from which alloys are formed, for example, during the filling process and (at least partially) fill the channel structures or perforations 12-1 of the substrate 12. Typical thicknesses of metal films and metal sheets may be in a range from 20 μm to 1000 μm or between 20 μm and 50 μm and (typically) about 30 μm.

In accordance with an embodiment, the metal film has the aluminum material as a main component with a volume fraction of >60%, >80% or even >90%. Furthermore, by the inventive manufacturing method 100, the electrically conductive channel structures 12-2 in the substrate 12 may fill a metal filling 14-1 to a degree of 90% or also between 95% and 98% and up to 100%, i.e. the channel structure 12-2 is filled completely (i.e. at least 90% or 98%), free of pores or inclusions.

In accordance with an embodiment, for example, temperature-resistant temporary carrier substrates 13 (see e.g. FIG. 18), such as silicon wafers, may be used for the pure aluminum melt filling of channel structures 12-1 in low-melting glass substrates 12, e.g. Schott BF33. These carrier substrates 13 may in turn be equipped with suction hole channels which are aligned with the bores in the glass substrate. The alignment may be realized by placing, by passive alignment aids (e.g. pins, balls) or by anodic bonding carried out before. The carrier substrate may be discarded after filling or may be configured with a non-stick coating for reuse.

In accordance with an embodiment, the filling may also be configured with a low melting point aluminum-copper alloy in the manufacturing method 100. This alloy may be introduced as a pre-alloyed film or may be formed in situ from (at least) an aluminum film and (at least) a copper film by forming an aluminum-copper eutectic during the heating phase of the pressure punch 32. The process temperature may thereby be lowered by about 100 K (compared to pure aluminum), which enables the filling of low melting point substrates 12, e.g. glass substrates, without deformation.

For example, the method 100 may be performed in a process chamber having a predetermined (e.g., inert) process atmosphere and a predetermined atmospheric process pressure.

The surface sealing element described in connection with FIG. 2A and the ring sealing element described in connection with FIG. 2B may readily be provided and/or used as independent structures. However, embodiments of the present invention provide for the two structures, i.e., the surface sealing element and the ring sealing element, to be used together. The joint use may be using both independent or individual structures. Alternatively, it is possible to firmly connect the surface sealing element and the ring sealing element to each other, for example by means of an adhesive process or bonding process, and to use the connected structure. As a further advantageous alternative, it is intended to provide the surface sealing element and the ring sealing element together as a single-piece or integral component and/or to use them as such.

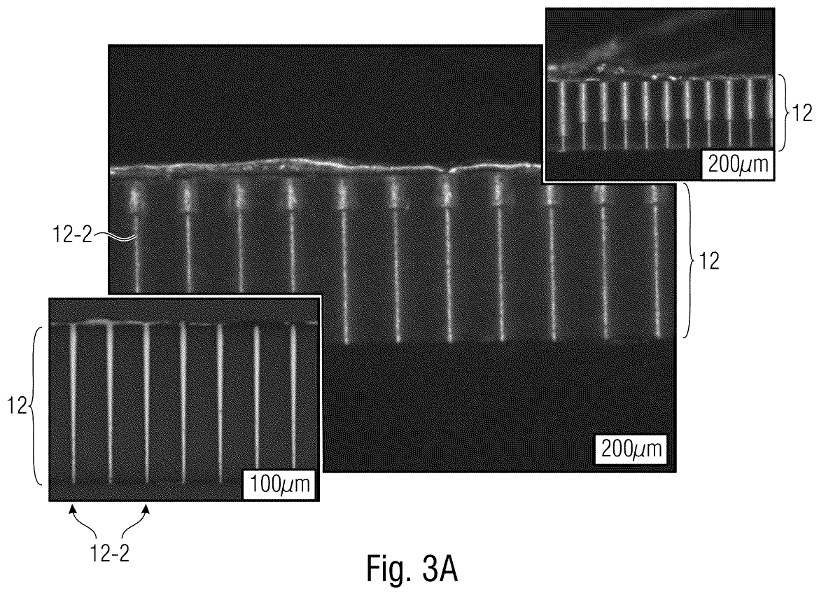

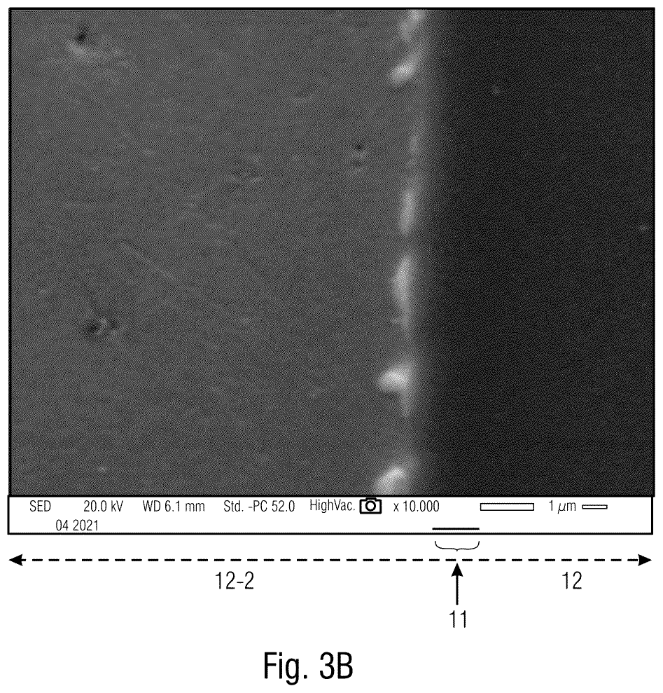

FIG. 3A shows exemplary Al-TGVs (aluminum through glass vias) in the substrate 12 (e.g. in glass or quartz glass) produced by the manufacturing method of FIG. 1 or FIGS. 2A-2B. FIG. 3B shows an exemplary detailed view of the interface connection 11 between the conductive Al filling 12-2 (of the Al-TGV) and glass 12 (e.g. borosilicate glass) produced by the manufacturing method 100 for high-pressure melt filling as shown in FIGS. 1 and 2A-2B.

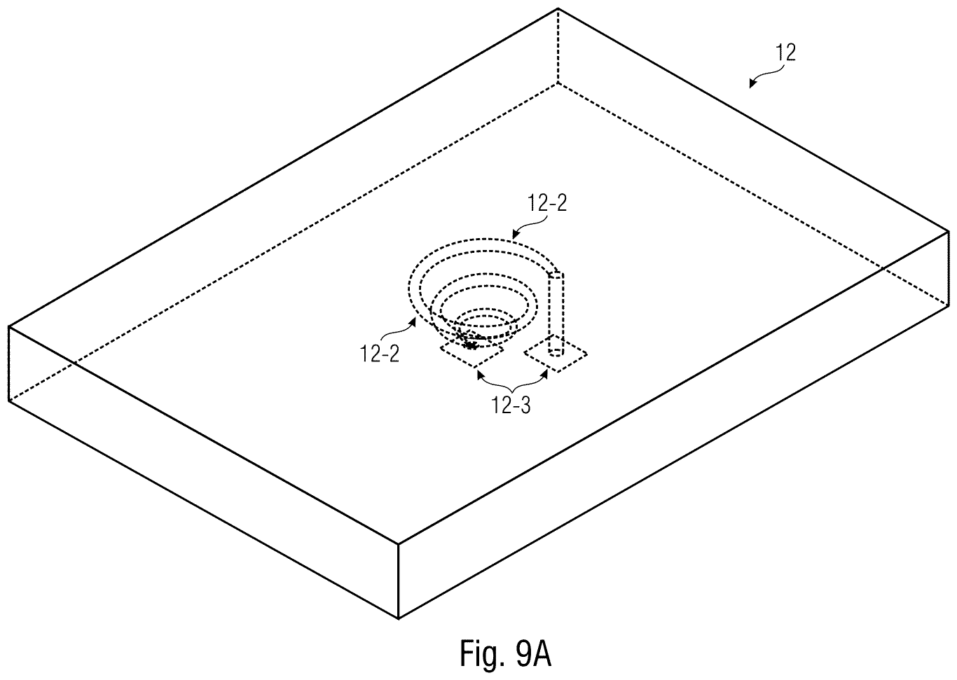

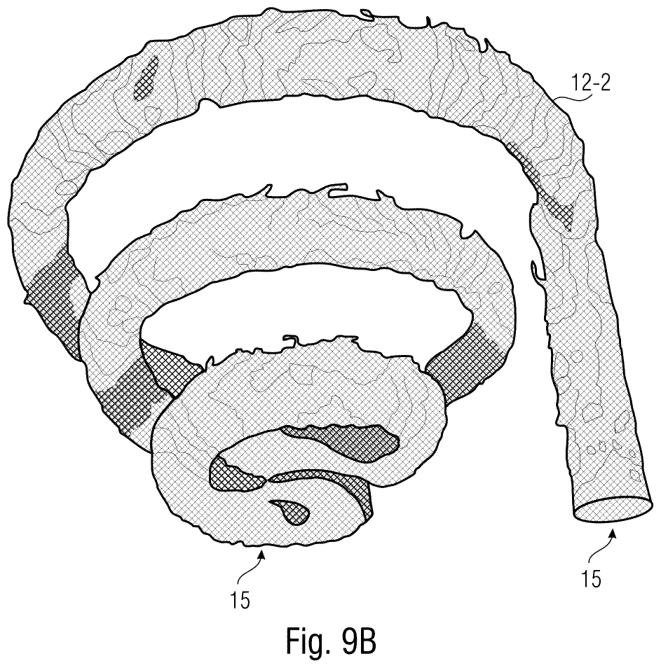

As can be seen from FIG. 3A, aluminum acts as its own adhesion promoter to glass, quartz, ceramic or sapphire substrates 12. Since an additional adhesion promoter layer may be omitted, Al vias may not only be produced much more easily according to the inventive manufacturing method, but the filling of real 3D structures is also possible, as exemplified in FIG. 9B.

In this context, it should be noted that aluminum acts as its own adhesion promoter to glass, quartz, ceramic or sapphire substrates, as shown as an example in FIG. 3B. Bonding to silicon substrates and oxidized silicon substrates is also possible. The provision of an additional adhesion promoter layer may therefore be omitted or is no longer necessary, which not only makes it much easier to produce the aluminum via compared to conventional manufacturing methods, but also makes it possible to fill real 3D structures at all.

The sidewall wetting or connection to the sidewall may optionally be improved by dielectric coatings. Conformal deposition ALD (atomic layer deposition) technology or LP-CVD (low pressure chemical vapor deposition) technology is particularly suitable for this purpose. Suitable dielectric layer materials for this are, for example, aluminum nitride (AlN), aluminum oxide (Al₂O₃), silicon nitride (SiN), titanium nitride (TiN) etc., e.g. having a thickness in the range from 5 to 100 nm or from 30 to 50 nm.

These dielectric layer materials may improve the filling of openings and allow filling at lower pressures. These layers may also act as additional barrier layers and may help to avoid unwanted reactions between the glass and the metallization. The focus here is not (necessarily) on the Al material, but (especially) on additives (alloys), such as copper. Copper, for example, may release monovalent ions which diffuse into the glass and, for example, impair the insulating properties or transparency of the glass.

The aluminum wettability of the channel structure may therefore be influenced favorably by a prior coating with SiN, AlN, TiN, etc. by an LP-CVD or ALD process. The layer thicknesses are in the range from 5 nm to 100 nm, or (advantageously) in the range from 30 to 50 nm. The (conformal) pre-coating may be used either to fill smaller via diameters (in a range of 5 to 15 μm) at the same process temperature and pressurization or, in the case of larger via diameters, to reduce the pressurization entailed in particular.

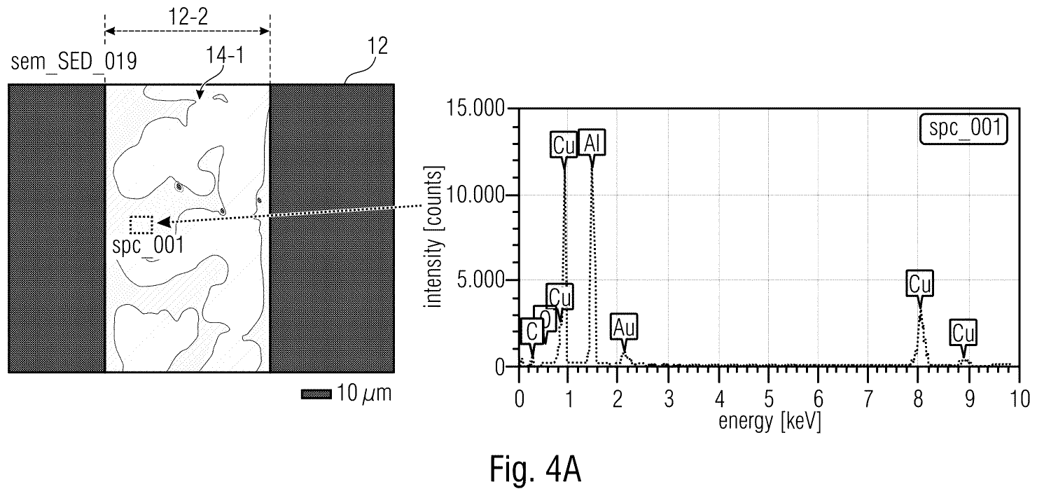

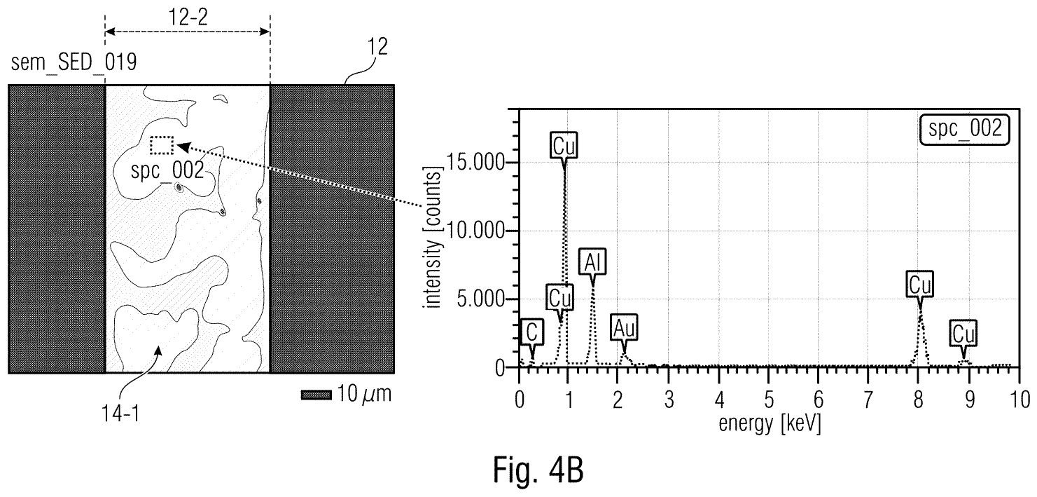

FIGS. 4A-4B show an example of an Al—Cu melt filling 14-1 in the channel structure 12-2 in a substrate 12 (e.g., a quartz substrate) produced by the manufacturing method 100 of FIG. 1 or FIGS. 2A-2B in accordance with an embodiment. In the example of an Al—Cu melt filling 14-1 in a quartz substrate 12 shown in FIGS. 4A-4B, for example, an Al—Cu roll-plated sheet is used. The aluminum material forms an adhesive coating to the substrate 12, while copper phases are present in the bulk body. The alloy is formed completely when the aluminum layer is melted by reacting with the copper layer. The aluminum side of the roll plating 14 is placed on the substrate 12 facing the (glass) substrate 12.

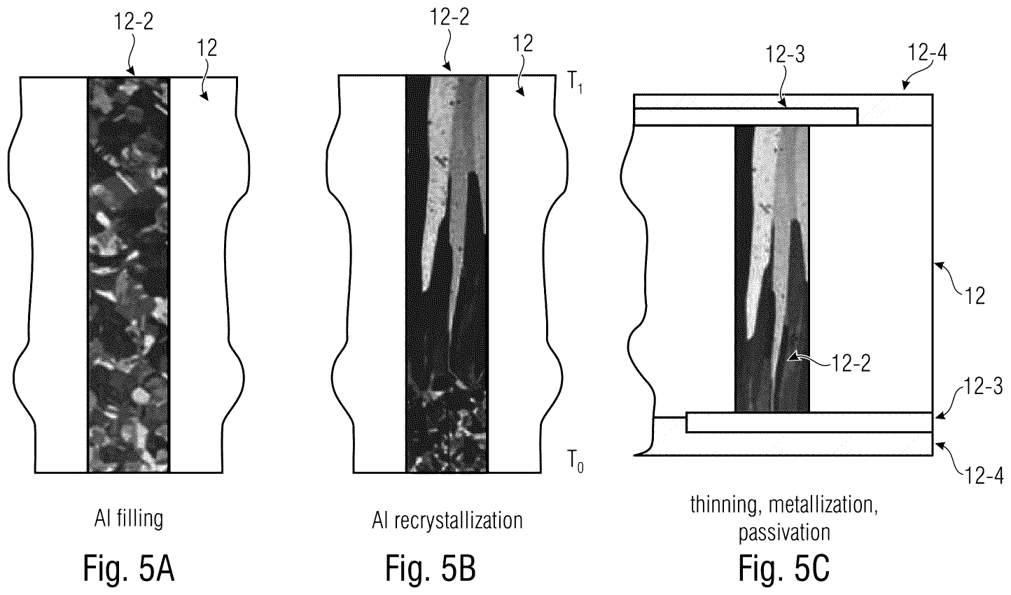

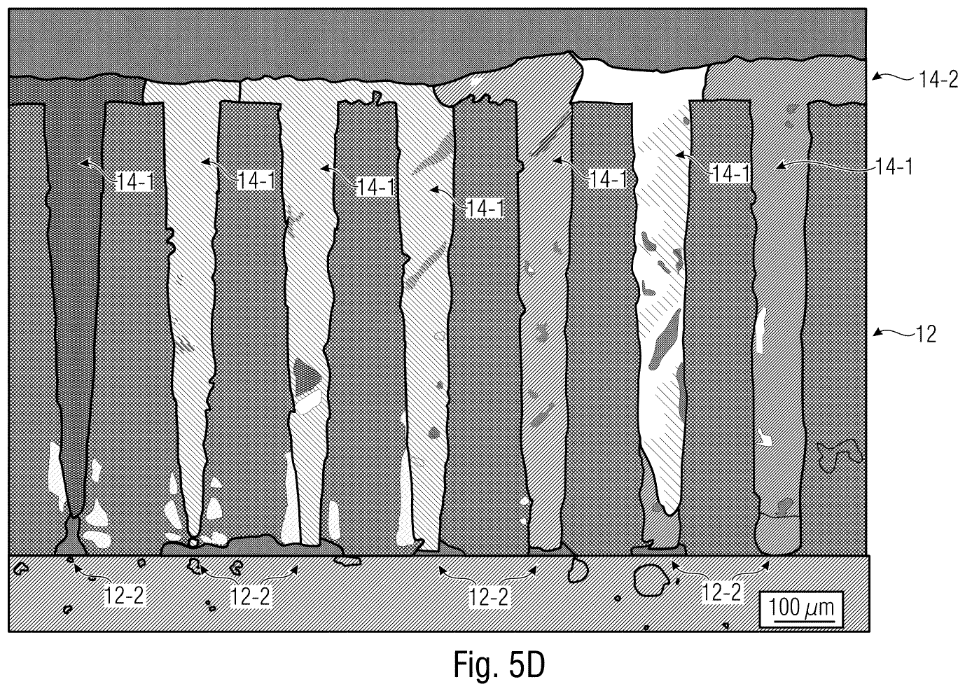

In accordance with an embodiment, the use of ultra-pure aluminum (4 N, 5 N or 6 N) may be considered for applications (e.g., a cryo-compatible arrangement of microelectrical components for quantum computing applications, e.g., at temperatures below 10 K) which are directed to particularly low contact resistances of the electrically conductive vias 12-2 through the substrate 12. The electron noise when passing through grain boundaries may be reduced by additionally tempering the substrate 12 (e.g. glass substrate) with the TGVs 12-2. The coarsest possible grain structure in the TGVs 12-2 having grain diameters in the range of the channel diameters of the channel structures 12-1 or larger is to be aimed at in order to achieve the lowest possible contact resistances and low electron noise. This tempering (additional tempering) is carried out, for example, at temperatures in the range of 250° C. to 500° C. in an oven. A further improvement in the electrical properties of already produced TGVs may be achieved by directional solidification of the microstructure, wherein a columnar grain structure (of TGVs 12-2) may be produced. In this context, reference is made, for example, to FIGS. 5A-5C, which show an exemplary procedure.

In the exemplary procedure illustrated in FIGS. 5A-5C, aluminum filling (according to the method 100) of the channel structure 12-1 in the substrate 12 is performed at first. As shown in FIG. 5B, Al recrystallization is performed during further tempering to obtain directional solidification of the Al structure 14-1 in the (filled) via 12-2. As exemplified in FIG. 5C, thinning of the substrate may be performed to highlight the columnar (column-shaped) grain structure in the via 12-2, whereupon, for example, metallization 12-3 and passivation 12-4 of contact pads may be performed. Thus, a concept of recrystallization by an impressed temperature gradient to produce columnar grain structures of the TGV produced by the method 100 may be obtained.

A further exemplary procedure for obtaining improved electrical properties of the vias (Al-TGVs) 12-2 in accordance with a further embodiment is exemplarily explained with reference to FIG. 5D.

In accordance with an embodiment, particularly low contact resistances of the electrically conductive vias 12-2 through the substrate 12 may be obtained, for example, by using ultra-pure aluminum (4 N, 5 N or 6 N). As exemplified in FIG. 5D, a single-crystal (mono-crystalline) via filling 14-1 may be achieved (in-situ), however, with different orientations in the vias 12-2, i.e., there are no grain boundaries in the metal material of the vias 12-2. Thus, the electron noise which occurs when passing through grain boundaries may essentially be avoided or at least greatly reduced with the monocrystalline vias 12-2.

This single-crystal via filling 14-1 of the vias 12-2 may be achieved, for example, by using high-purity aluminum (Al content >98%) or ultra-pure aluminum (Al content=100%) in the method 100 for pressure filling. Furthermore, exerting 140 the process temperature T_{P} (peak temperature) on the stack arrangement 10 may take place, for example, for (relatively long) 5 to 40 seconds or 10 to 30 seconds. Further, the cooling process 160 may, for example, take place at a relatively low (mean) temperature change (cooling) of 20 to 300 K (or 30 to 200 K) per minute (until a normal temperature of, for example, 290 K to 300 K is reached) (Ostwald ripening).

The inventive manufacturing method 100 for manufacturing an electrically conductive channel structure 12-2 in a substrate 12 opens up many new application possibilities, which are (by far) not limited to the field of high-frequency technology or quantum technology.

Compared to previous methods in microtechnology, which realize a 2.5-D technology (extension of 2D structures in depth), new possibilities for manufacturing 3D-formed microstructures or channel structures are made possible by the inventive procedure, e.g. using SLE (selective laser-induced etching) processes.

The inventive manufacturing method 100 for manufacturing an electrically conductive channel structure 12-2 in a substrate 12 based on aluminum melt filling of hole and blind hole structures 12-1 in substrates 12, e.g. glass and oxidized silicon substrates, is not limited to (entirely) specific processing methods for manufacturing the hole structures. For example, structuring methods with very high aspect ratios in substrates 12 (e.g. glass substrates) are of particular interest for applications in microelectronics, especially with thermomechanical expansion coefficients which are largely adapted to silicon. The term glass substrate is to be understood here to mean technical glasses and IR-transparent ceramics (e.g. in the range around 1 μm wavelength—for laser-induced etching) with a low coefficient of thermal expansion 0 ppm/K<CTE<6 ppm/K (CTE=coefficient of thermal expansion) (e.g. sapphire, AlN, Si3N4, SiC, glass ceramic) to synthetically produced quartz glass (fused silica) having an expansion coefficient of (approximately) ˜0.1 ppm/K. A ceramic substrate may, for example, be provided with holes which can also be filled according to the procedure described.

Filling hole structures 12-1 is also possible in silicon (in a silicon substrate 12) with and without surface oxidation, e.g. for producing electrical feedthroughs and heat dissipation vias. In silicon, a barrier may separate the silicon and the hot Al. The barrier may be or comprise SiO2, wherein deposited layers, such as Si₃N₄, are also suitable for this purpose.

The substrates 12 (e.g. glass, silicon substrates, etc.) are used, for example, in wafer form with plane-parallel top and bottom sides. However, (glass) flat substrates with other dimensions may also be used, for example, to produce meta materials with specifically adjusted reflection or transmission properties for high-frequency electromagnetic radiation (5G, 6G, radar, THz). Metamaterials are artificially produced materials having optical, electrical or magnetic properties which do not occur in nature.

Possible methods of high detail resolution for hole production rely, for example, on laser exposure (usually fs to ns pulse duration) to locally increase a glass etching rate and subsequent etching either in KOH, NaOH solution or in hydrofluoric acid (HF). Other wet chemical etching processes are also conceivable. Due to the different laser processing methods and the different etching properties of the glasses depending on their chemical composition, different hole geometries are also produced, especially if the degree of freedom of double-sided or single-sided etching is taken into account. The formation of the channel structures 12-1 and wall angles depends on the substrate material, e.g. the glass material, the laser focal resolution, the exposure strategy and the etching chemistry used, etching duration, etc.

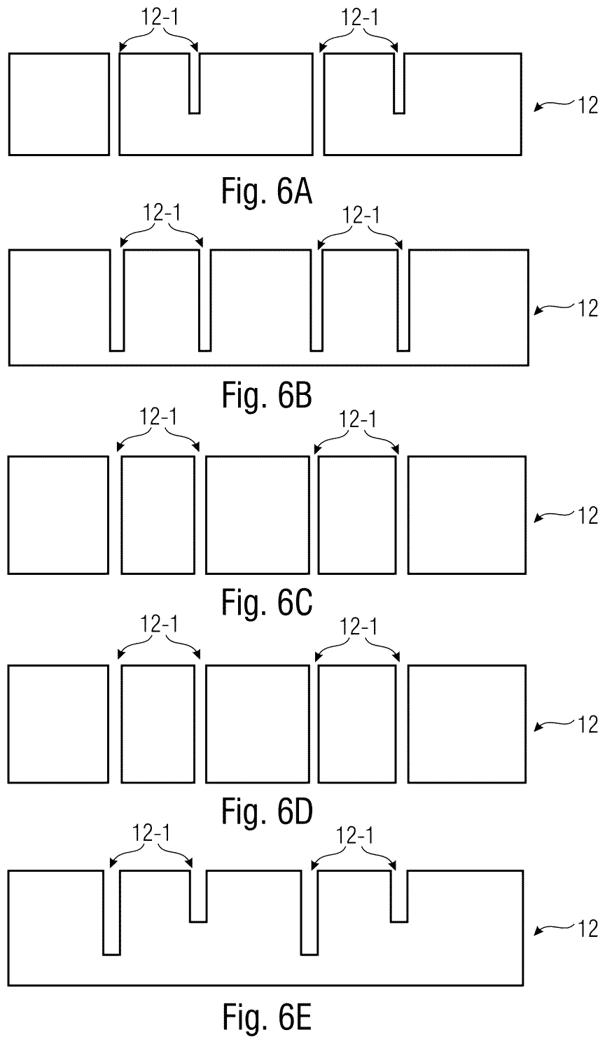

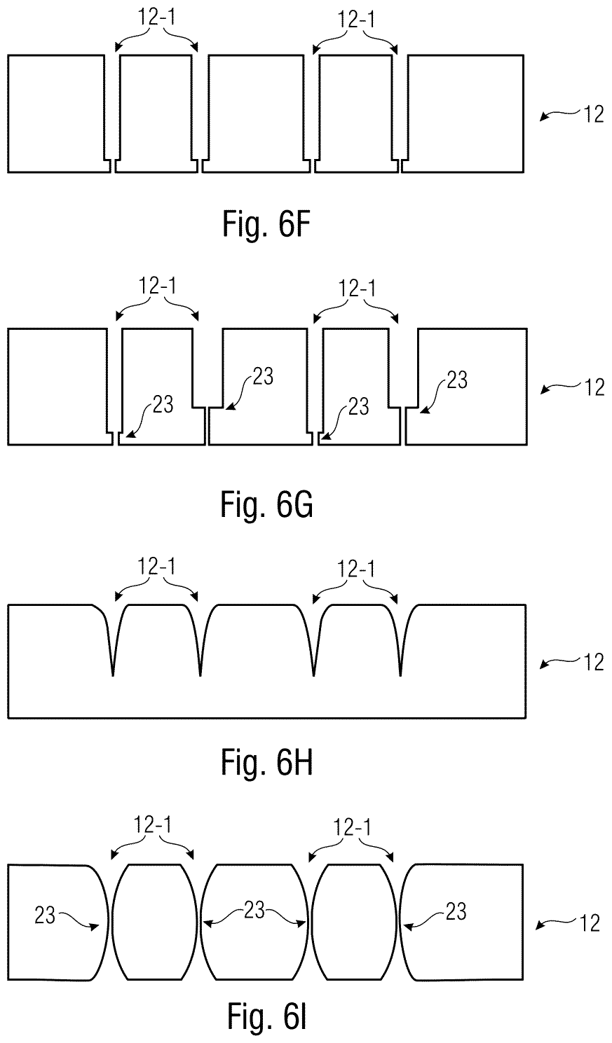

FIGS. 6A-6I show exemplary geometries of channel structures with different dimensions and wall angles for filling by the inventive manufacturing method 100 according to FIG. 1 or FIGS. 2A-2B.

For example, as shown in FIG. 6A, a quartz substrate 12 is etched by LIDE (Laser Induced Deep Etching) on both sides with a patterned additional protective mask to obtain both the continuous through hole geometries 12-1 and the blind hole geometries 12-1. The protective mask has opposite openings on both sides to obtain the continuous hole geometries and an opening on one side only to obtain the blind hole geometry of the channel structures 12-1.

FIG. 6B shows an example of the substrate 12, e.g. a quartz substrate, which was etched on one side using LIDE, for example, in order to obtain the channel structures 12-1 with a blind hole geometry.

As shown in FIG. 6C, the substrate 12, e.g. a quartz substrate, may be etched through on one side using LIDE to obtain the continuous hole geometries of the channel structures 12-1.

As shown in FIG. 6D, the substrate 12, for example a quartz substrate, may be etched on both sides using LIDE to obtain the continuous hole geometries of the channel structures 12-1.

As shown in FIG. 6E as an example, the substrate 12, e.g. a quartz substrate, may be etched on both sides by means of SLE (Selective Laser-Induced Etching) in order to obtain different hole geometries (blind hole depths) of the channel structures 12-1.

As shown in FIG. 6F as an example, the substrate 12, e.g. a quartz substrate, may be etched on both sides by means of SLE in order to obtain different hole geometries (hole diameters) of the channel structures 12-1. Furthermore, for example, a flow stop for the liquefied metal material 14-1 is produced by the narrowed hole geometry (constriction) 23.

FIG. 6G shows, for example, the substrate 12, e.g. a quartz substrate, which has been etched on both sides by means of SLE in order to obtain different hole geometries, i.e. different hole diameters of the channel structures 12-1 at different substrate depths. Furthermore, for example, a flow stop for the liquefied metal material 14-1 is produced by the narrowed hole geometry (constriction) 23.

FIG. 6H shows the substrate 12, e.g. a glass substrate (e.g. Schott AfF2 eco), in which the hole geometries of the channel structures 12-1 have been etched on one side using LIDE.

FIG. 6I shows the substrate 12, e.g. a glass substrate 12 (e.g. Schott Af32 eco), in which the hole geometries of the channel structures 12-1 have been etched on both sides using LIDE (continuous hole geometries). Furthermore, for example, a flow stop for the liquefied metal material 14-1 is created by the narrowed hole geometry (constriction) 23.

In summary, it may therefore be noted that the substrates 12 shown in FIGS. 6A-6I have different hole geometries and flank angles of the channel structures 12-1.

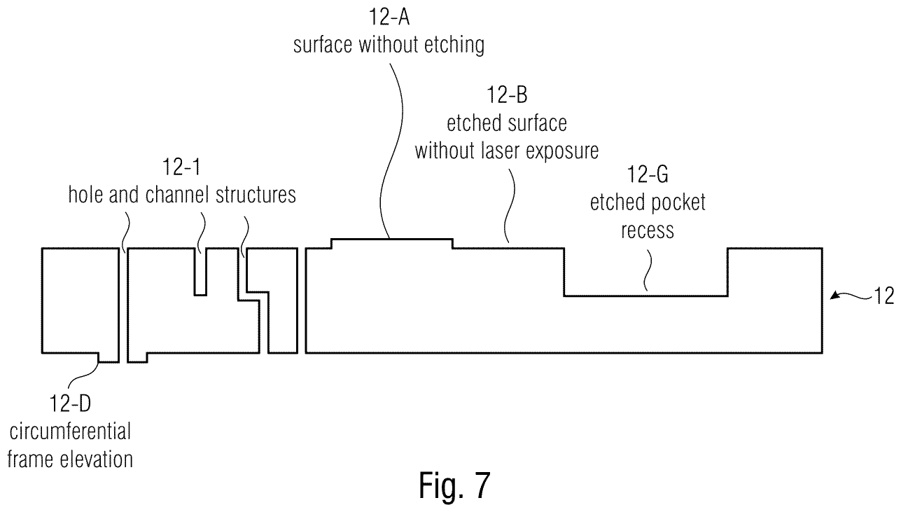

FIG. 7 shows a schematic representation of further possible topologies of the substrate 12 for use in the inventive manufacturing method of FIG. 1 or FIGS. 2A-2B.

For example, structured protective masks (e.g. structured by means of photolithography) can also be used on one or both sides in an etching process of the substrate 12 to obtain the channel structures 12-1, which restrict or prevent the etching attack on certain substrate regions and allow/enable it on other regions. This can be used, for example, to create raised regions on the substrate 12 or also some regions only after other regions, e.g. after further processing of the wafers, downstream in the manufacturing process deep etching.

The surface region 12-A of the substrate 12 has, for example, no etching. The surface region 12-B of the substrate 12 has, for example, an etched surface without laser exposure. The surface region 12-C of the substrate 12 has, for example, an etched pocket recess. The surface region 12-B of the substrate 12 has, for example, a circumferential frame elevation.

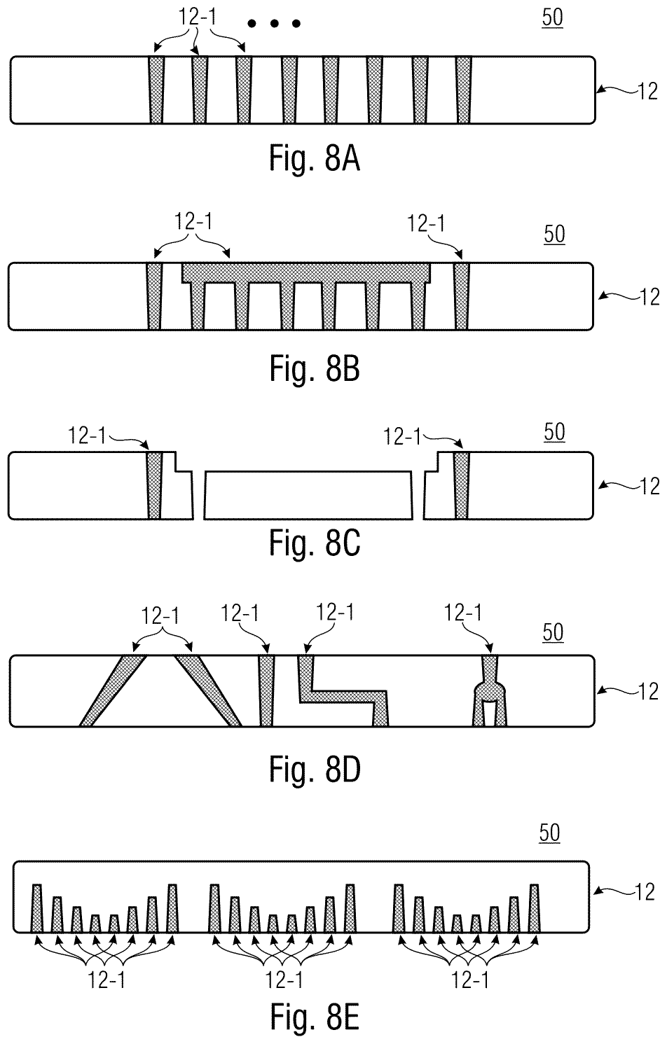

FIGS. 8A-8E, 9A-9B, 10, 11, and 12A-12B describe exemplary implementations of an interposer arrangement 50 or a part of the interposer arrangement 50 in accordance with further embodiments.

The interposer arrangement 50 includes a substrate 12 having an electrically and/or thermally conductive channel structure 12-2 extending at least partially through the substrate 12, wherein the channel structure 12-2 includes an aluminum material or an aluminum material alloy, and wherein the electrically and/or thermally conductive channel structure 12-2 extends into the substrate 12 from a main surface region of the substrate 12.

The aluminum material or the aluminum material alloy has at least 80% or 90% aluminum as its main component in order to have a resulting melting point of at least 420° C. (or 520° C.) or between 420° C. (or 520° C.) and 850° C. as brazing hard solder.

In accordance with an embodiment of the interposer arrangement 50 (see FIGS. 8A-8D), the conductive channel structure 12-2 extends from one main surface region of the substrate 12 into the substrate 12 and to the opposite main surface region of the substrate 12.

In accordance with an embodiment of the interposer arrangement 50 (see FIGS. 8B and 8D), the conductive channel structure 12-2 does not extend, at least in sections, in a direction vertical to the two opposing main surface regions of the substrate.

In accordance with an embodiment of the interposer arrangement 50 (see FIGS. 8A-8C and 8E), the conductive channel structure 12-2 extends vertically to the two opposing main surface regions of the substrate 12.

In accordance with an embodiment of the interposer arrangement 50 (see FIGS. 8A-8E), the electrically and/or thermally conductive channel structure 12-2 is configured as at least one thermal connection made of aluminum for heat dissipation through the substrate 12 (between the first and second opposing main surface regions).

In accordance with an embodiment of the interposer arrangement 50 (see FIGS. 8A-8E), the conductive channel structure 12-2 is configured as at least one electrical via through the substrate 12 and/or as at least one passive component in the substrate 12.

In accordance with an embodiment of the interposer arrangement 50 (see FIGS. 8A-8E), the at least one via 12-2 through the substrate 12 has an aspect ratio of 50:1 (length to diameter).

An interposer or an interposer arrangement 50 refers to, for example, an electrical interface which leads a socket or a connection level to another connection level. The purpose of an interposer is, therefore, to distribute a connection level to a larger connection field, for example, or to divert a connection level to another, different connection level.

Thus, FIGS. 8A-8E show schematic representations of exemplary interposer arrangements 50 (having further possible substrate topologies) in accordance with further embodiments which may be obtained, for example, using the manufacturing method 100 of FIG. 1 or FIGS. 2A-2B according to the invention.

FIGS. 8A-8E show various topographies and hole geometries for the interposer arrangement 50, which can be produced by SLE and LIDE laser exposure and subsequent one-sided or two-sided etching in the substrates 12, e.g. glass substrates. With local etch protection, protected areas may only be etched downstream, e.g. after metallization or via filling. For example, recessed surface recesses 12-1, blind holes 12-1, channel structures 12-1 and open via holes 12-1 can be introduced into substrates 12 which are otherwise already metallized on one or both sides, by protecting the metallizations 12-2 from an etching attack by means of protective masks.

FIGS. 8A-8E show filled vias (fully or partially continuous via openings) in various possible geometries. A via channel 12-2 may also start and end on the same side of the substrate 12. A via channel 12-2 may also split and begin or end with a different number of arms between the first and second opposing main surface regions of the substrate 12 (see FIG. 8D).

FIG. 9A shows an exemplary 3D channel structure 12-2 (e.g., a 3D helix) in the substrate 12, which may be manufactured, for example, by the inventive manufacturing method 100 of FIG. 1 or FIGS. 2A-2B. As shown in FIG. 9A, the electrical contacts 12-3 may be arranged on the same main surface side of the substrate 12. FIG. 9B shows an enlarged 3D X-ray tomography image of the 3D helix of FIG. 9A. The 3D helix 12-1 may, for example, be manufactured in the substrate 12, e.g. a glass substrate, by means of the manufacturing method 100 of FIG. 1 or FIGS. 2A-2B. Here, FIG. 9B shows the channel structure 12-2 produced after the SLE method in quartz or glass with the aluminum pressure filling (via the filling openings 15) according to the method 100 of FIG. 1 or FIGS. 2A-2B as a 3D X-ray tomography image.

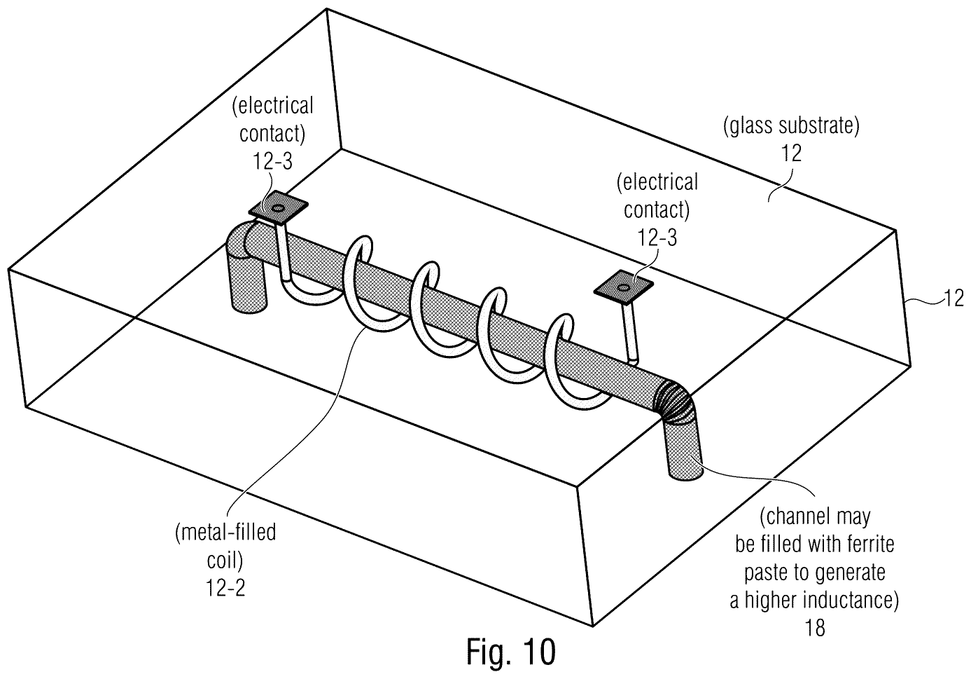

FIG. 10 shows an exemplary, perspective view (3D view) of a component in the form of a metal-filled helix 12-2 in a substrate (e.g. glass substrate) 12, e.g. manufactured by the manufacturing method 100 of FIG. 1 or FIGS. 2A-2B. As shown in FIG. 10, the electrical contacts 12-3 may be arranged on the same main surface side of the substrate 12. The metal-filled helix 12-2 in the substrate 12 may, for example, be arranged in the direction of extension around a channel 18, wherein the channel 18 in the substrate 12 may have a filling with a ferrite paste in order to generate a higher inductance of the coil (helix) 12-2. The coil (helix) 12-2 may, for example, also be configured to be flat in a plane and be provided with a coil core.

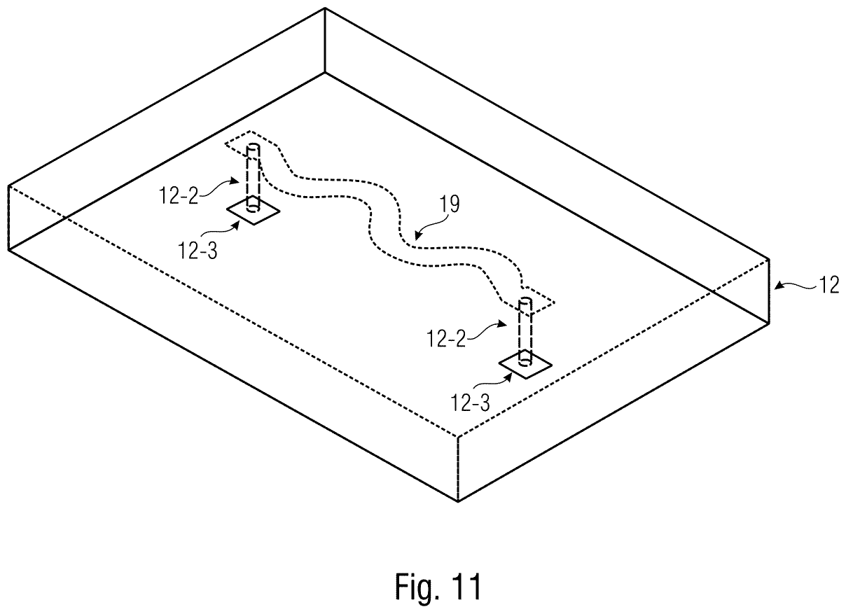

FIG. 11 shows an exemplary perspective view of a device in the form of a thin film getter structure 19 having via contacting 12-2 through the substrate 12 and manufactured, for example, by the manufacturing method 100 of FIG. 1 or FIGS. 2A-2B. As shown in FIG. 11, the thin film getter structure 19 has a via contacting 12-2 from the back side, i.e. the electrical contacts 12-3 are arranged on the same main surface side of the substrate 12 to enable heating of the thin film getter structure 19 (for getter activation) via the via contacting 12-2.

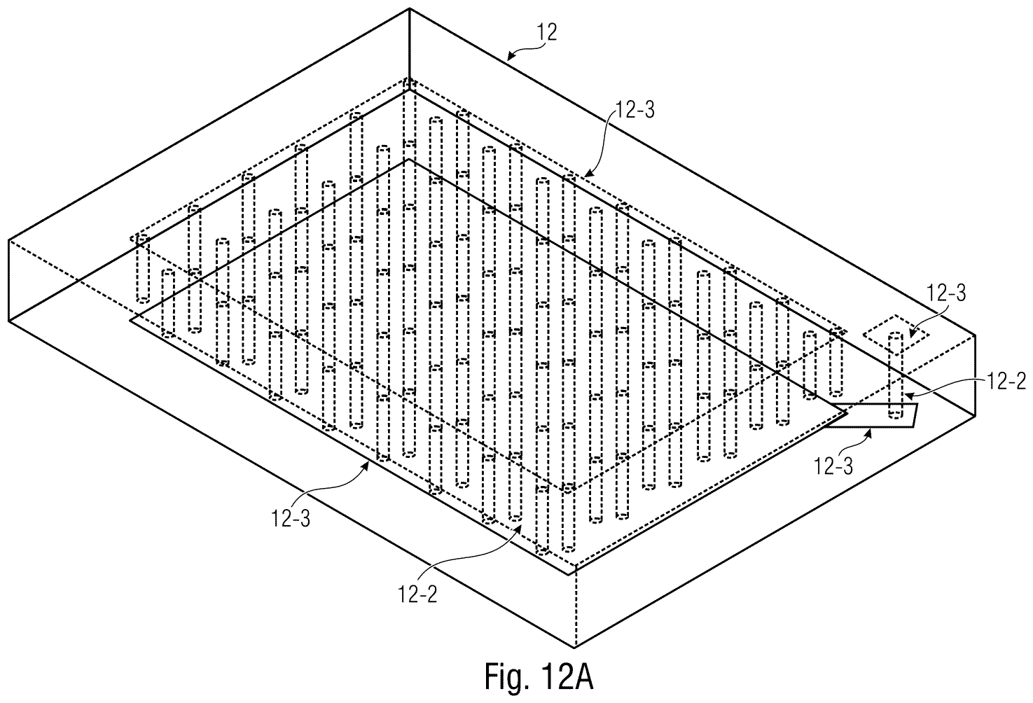

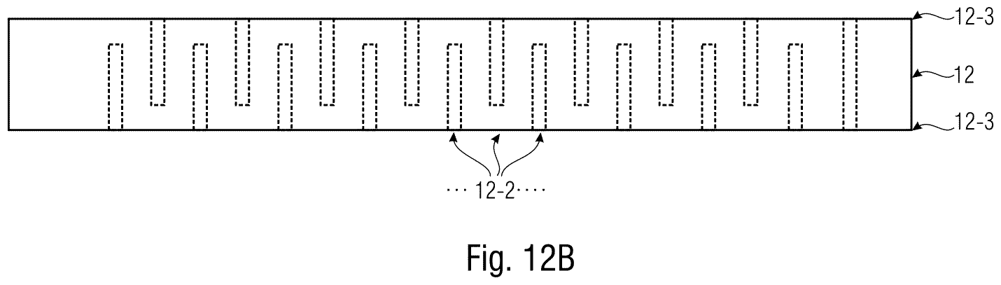

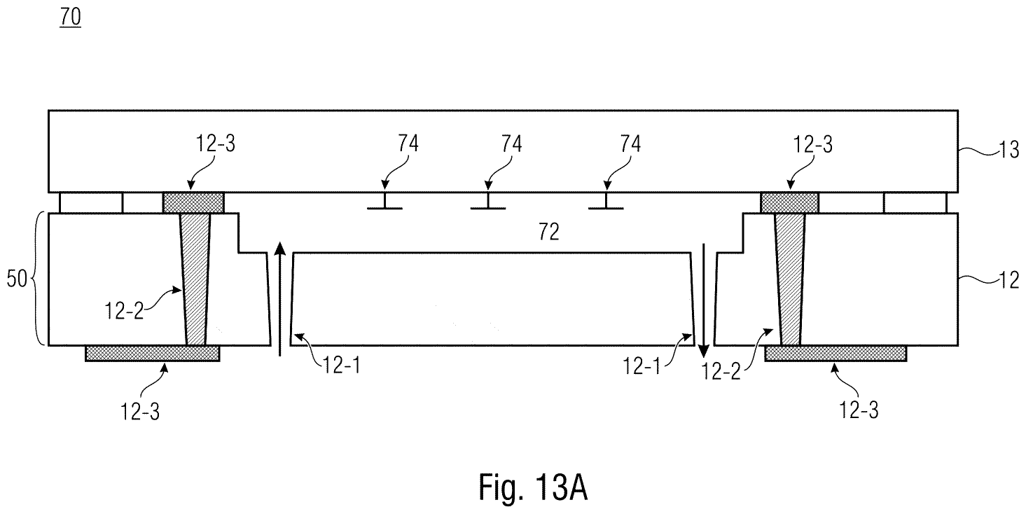

FIGS. 12A-12B show an exemplary perspective view and an exemplary cross-sectional view of a component in the form of a capacitor structure manufactured by the manufacturing method 100 of FIGS. 1 and 2A-2B. Using the manufacturing method 100, the capacitor arrangement 60 may be manufactured having opposing contact surfaces 12-3 and pin electrodes 12-2.

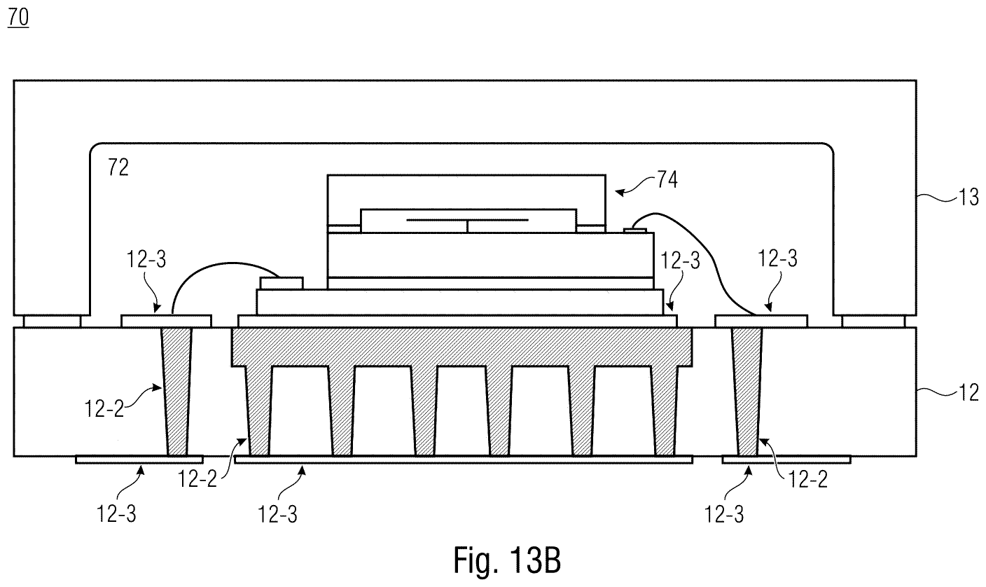

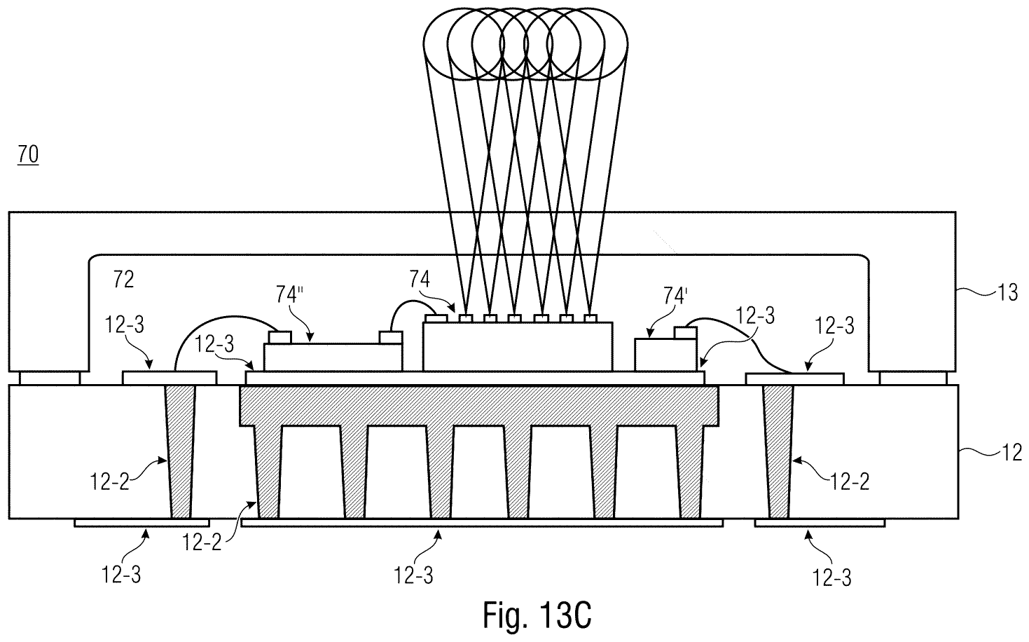

FIGS. 13A-13C show exemplary cross-sectional views of packaged components 70, such as MEMS, sensors and/or ICs, with the Al vias 12-2, e.g. Al TGVs, in the substrate 12 and manufactured, for example, by the manufacturing process 100 of FIG. 1 or FIGS. 2A-2B, for electronic connection as electrical vias 12-2 and/or for thermal connection 12-2 (for heat dissipation) in accordance with a further embodiment.

As exemplified in FIG. 13A, the conductive channel structure 12-2 in the substrate 12 may be used to mechanically and/or electrically connect another substrate 13. Furthermore, through openings 12-1 in the substrate 12 may be provided as fluidic, acoustic, etc. access and/or exit openings to a cavity 72 arranged between the two substrates 12, 13 and having an electrical and/or mechanical component 74.

As shown in FIG. 13B, the conductive feedthroughs 12-2 may be provided in the substrate 12 for electrically connecting (rewiring) and/or thermally connecting (for dissipating heat to a heat sink) an electronic device 74, the electronic device 74 being arranged in a cavity 72 on the substrate 12, arranged between the two substrates 12, 13.

As shown in FIG. 13C, the conductive feedthroughs 12-2 may be provided in the substrate 12 for electrically connecting (rewiring) and/or thermally connecting (for dissipating heat to a heat sink) an opto-electronic device 74 (having several individual elements 74, 74′, 74″), the opto-electronic device 74 being arranged in a cavity 72 on the substrate 12, arranged between the two substrates 12, 13.

In the arrangement of FIGS. 13A-13B, the electronic component 74 may comprise a mechanical component (MEMS component), while in FIG. 13C the arrangement may comprise an optoelectronic component (e.g. having high heat dissipation).

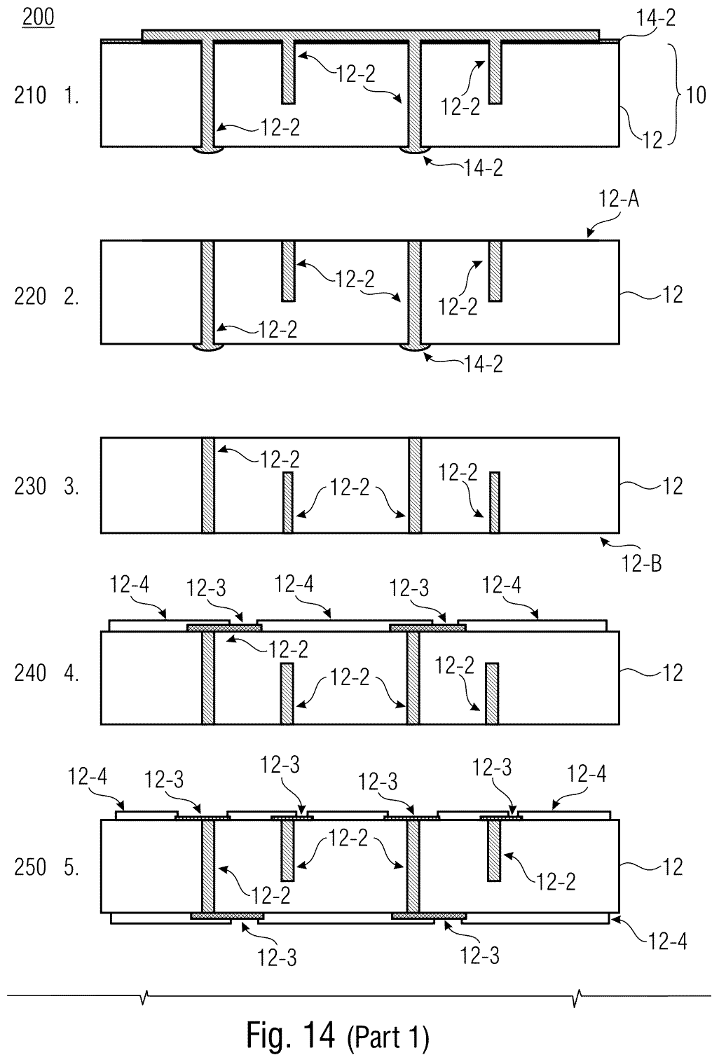

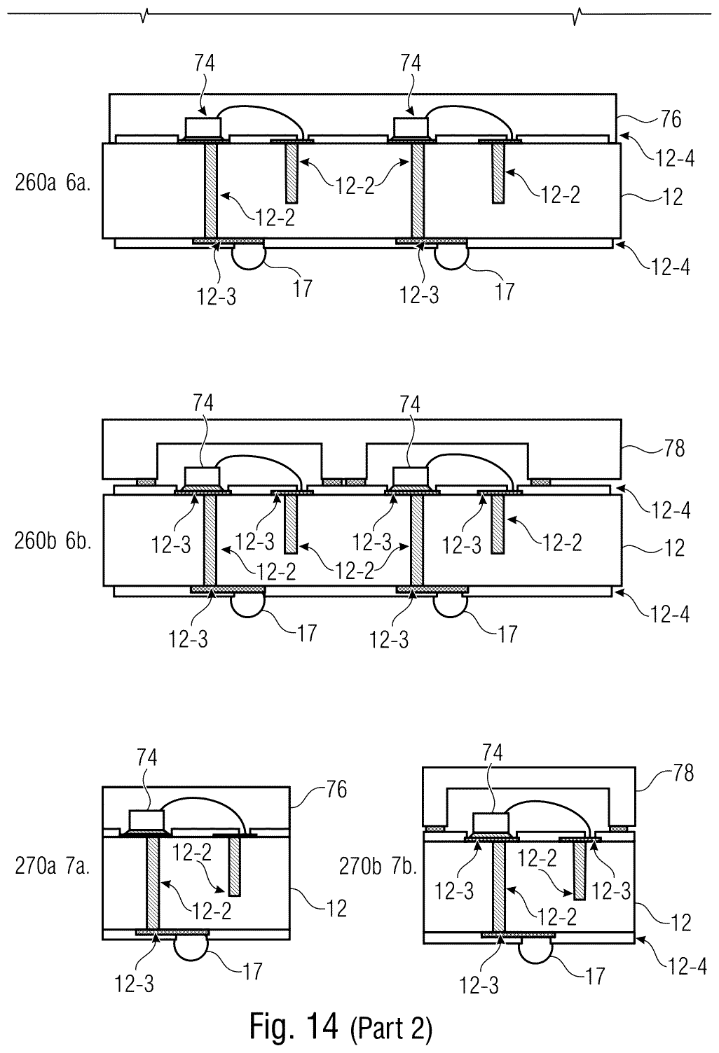

FIG. 14 shows an exemplary, basic (schematic) flow diagram 200 for further processing (e.g. on wafer level) of the stack arrangement 10 obtained by the manufacturing method 100 of FIG. 1 or FIGS. 2A-2B.

As will be described below in greater detail, the method 200 may further remove excess metallic filling material 14-2 from one side of a main surface region or from both sides of opposing main surface regions of the substrate 12, for example by means of a chemical mechanical polishing (CMP) process. Furthermore, in the method 200, metallization may be performed on one or both sides of the substrate 12 by means of a thin film deposition process to obtain, for example, a metallization structure 12-3 electrically connected to the conductive channel structure 12-2 on one or both main surface regions of the substrate 12 formed with the conductive channel structure 12-2, via a lithographic patterning process and a subsequent etching step.

As shown in sub-image 1 (step 210) of FIG. 14, the stack arrangement 10 processed according to the method 100 of FIG. 1 or FIGS. 2A-2B, i.e. the substrate 12 provided with the electrically conductive channel structure 12-2, forms the starting point for further processing (e.g. on wafer level) according to the method 200. For example, the substrate 12 comprises a plurality of conductive channel structures 12-2 having a plurality of conductive vias and a plurality of blind holes (or passive components).

The substrate (wafer) 12 thus comes from the Al-filling process 100, wherein the substrate 12 has, for example, channel structures 12-2 filled with an AlGe solder material (solder), wherein all other options described before are equally applicable to the material composition of the metal film 14.

The following exemplary process steps, as exemplified in the following sub-images, may be applied to obtain an interposer arrangement 50 (e.g., a glass interposer) having integrated passive components and/or active components, e.g., an RF transistor, as part of further wafer processing 200. This combination of components is to be regarded merely as an example of the resulting interposer arrangement 50.

As shown in sub-step 2 (step 220) of FIG. 14, conditioning or processing of the substrate top side (wafer top side) 12-A of the substrate 12 may be performed by an etching or grinding and polishing process (CMP process).

As shown in sub-step 3 (step 230) of FIG. 14, conditioning of the substrate bottom side (wafer bottom side) 12-B of the substrate 12 may be performed by an etching or grinding and polishing process (CMP process).

As shown in sub-step 4 (step 240) of FIG. 14, processing of the substrate top side (wafer top side) 12-A of the substrate 12 may be performed with any patterned metallizations 12-3 and any passivation layers 12-4. The process flow may also utilize the substrate top side (wafer top side) 12-A of the substrate 12 in this step.

As shown in sub-image 5 (step 250) of FIG. 14, the processing executed in sub-image 4 (step 240) with the substrate top side 12-A may likewise be carried out on the substrate bottom side (wafer bottom side) 12-B, if necessary with resistive layers 12-5.

Sub-image 6a (step 260a) of FIG. 14 shows an exemplary option in which a solder (soldering agent) 17 is applied to corresponding contact surfaces 12-3 and the active component 74, for example a transistor, is mounted/attached. In the optional embodiment shown in sub-image 6a, a cover 76 having the top surface 12-A (wafer top surface) of the substrate 12 (wafer) may be obtained by means of a mold compound (potting compound).

The components/assemblies 74 may then (in step 270a) be diced (on wafer level). The separated assembly 74 is shown as an example in sub-image 7a.

As exemplified in the sub-image 6b (step 260b) of FIG. 14, a solder 17 may be applied to the contact pads 12-3 on the second main surface 12-B of the substrate 12, further mounting the (e.g., active) device 74, e.g., a transistor, to corresponding contact pads 12-3. In the optional embodiment shown in sub-image 6b, hermetic covering of the substrate top surface (wafer top surface) may be obtained by means of a further substrate 78 provided with cavities, e.g. a glass or silicon wafer.

The components/assemblies 74 may then (in step 270b) again be diced, with sub-image 7b showing an example of a diced assembly.

As exemplified in the sub-images of FIG. 14, the passive component, i.e., the channel structure 12-2 configured as a blind hole, may also take any other suitable forms to provide the passive component associated with the transistor. Thus, the manufacturing method described with reference to FIG. 1 or FIGS. 2A-2B, for filling channel structures 12-1 (e.g., 3D channels) in the substrate 12 may be used to manufacture embedded passive components 12-2, such as coils with and without cores, coils having fluid channels for medical applications, antennas, capacitors, etc.

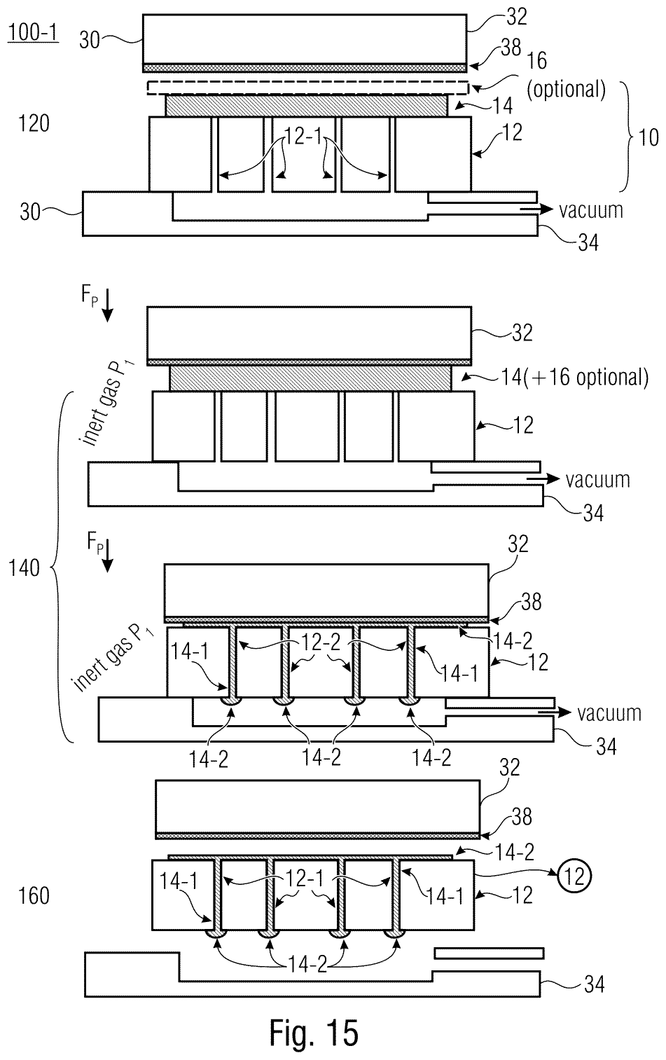

In the following, further procedures (schematic flow diagrams 100-#of the method 100) for manufacturing an electrically conductive channel structure 12-2 in a substrate 12 are described with reference to FIGS. 15-22, wherein optional implementations of the clamping device 30 and its mode of operation and different implementations of the stack arrangement 10 may be applied to the manufacturing method 100 described before. These further optional implementations may, for example, support the function of the compressible sealing element (area sealing or ring sealing element) 16 of FIG. 1 or FIGS. 2A-2B, although the compressible sealing element 16 is not explicitly shown in some alternatives of the manufacturing method 10 described below.

In the further embodiments 100-1-100-8 (100-#) of the flow diagram of the manufacturing method 100 shown in FIGS. 15-22 below, the method steps shown with reference to FIGS. 1 and 2A-2B are again essentially carried out, with the additions and changes (differences) compared to the manufacturing method 100 described before being shown below in particular. Furthermore, identical elements, objects, functional blocks and/or method steps or those of identical function or identical effect in the different figures are provided with the same reference numerals so that the description of these elements, objects, functional blocks and/or method steps (having the same reference numeral) shown in the different embodiments is interchangeable or mutually applicable.

Exemplary implementations for realizing a suction vacuum are described below (see also the embodiments with reference to FIGS. 15-22), wherein the vacuum for sucking the melt 14-1 into non-continuous hole structures (blind holes) 12-1 may be produced in different ways.

A vacuum may be applied in particular for through holes or blind holes 12-1 having a very thin tap through a vacuum chuck 34 from the bottom of the glass substrate 12 to be filled. In terms of process technology, it may be complex to use the negative pressure as a controlling variable. Nevertheless, it is of advantage to be able to dynamically control the vacuum in order to avoid excessive soaking of the melt 14-1 through through-holes. A flat covering substrate 32 (having a non-stick coating of BN, carbon, etc.) under controlled contact pressure F_{P} (e.g. mechanically plus hydraulically by flooding the chamber (=process chamber) with inert gas) prevents the aluminum film 14 from contracting during melting and sags in the direction of the substrate 12 to be filled during filling of the through holes 12-1. The covering substrate 32 thus forms an overlying mechanical valve to reduce the flow rate of the melt through through-holes 12-1. On the other hand, the covering substrate 32 avoids the top contact of the melt 14-1 having contact with the ambient atmosphere, wherein the formation of surface nitrides and oxides on the aluminum can be avoided.

FIG. 15 shows an exemplary, principle flow diagram 100-1 with respect to an alternative procedure for producing an electrically conductive channel structure 12-2 in the substrate 12 by introducing a metallic filling material 14-1 into the channel structure(s) 12-1 in accordance with a further embodiment (insofar as a compressible sealing element 16 is used).

In accordance with an embodiment of the flow diagram 100-1 of the method 100 of FIG. 15, in step 120, a substrate 12 (e.g., a perforated glass wafer) provided with a channel structure 12-1, with an aluminum film 14 (anodically bonded) is placed on the second tool 34 (e.g., a vacuum chuck) and sucked thereon. The metal film 14 comprising the aluminum material may, for example, be anodically bonded to the substrate 12.

An anodically bondable substrate 12 (e.g., a glass substrate) is used in order to perform the process flow 100-1 having an anodically prebonded aluminum film (a metal film comprising aluminum material) 14. In step 140, in an inert gas environment having an atmospheric pressure (e.g., positive pressure P₁), the metal film (aluminum film) 14 may be pressed against the substrate 12 with the upper (coated) stop 32 (first tool) and heated. This melts the metal film, wherein the channel structures (e.g. holes) 12-1 in the substrate 12 are filled at least partially or completely. The filling of the channel structures 12-1 is thereby assisted by the atmospheric (suction) negative pressure (vacuum) provided by the second tool 34 (vacuum chuck).

In step 116, the processed stack arrangement 10 is cooled, and after cooling and ventilating the process chamber and switching off the vacuum suction, the substrate 12 (i.e. the filled wafer) provided with the electrically conductive channel structure 12-2 can be removed.

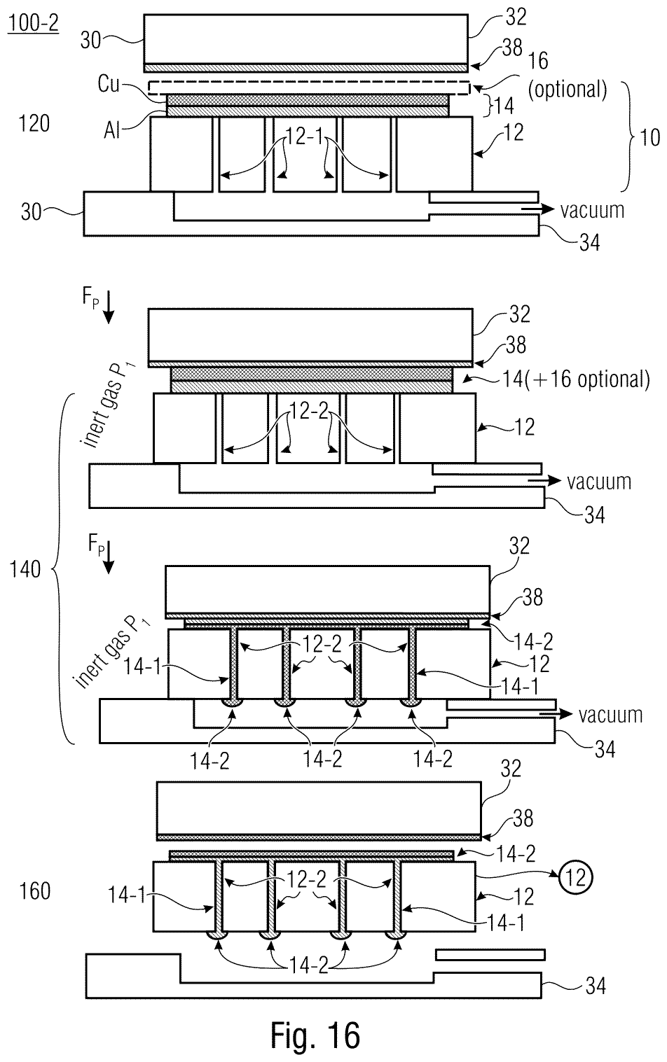

Referring now to FIG. 16, a further, exemplary, principal flow diagram 100-2 of the manufacturing method 100 for manufacturing an electrically conductive channel structure 12-2 in a substrate 12 by introducing a metallic filling material 14-1 in accordance with a further embodiment will be described.

The process 100-2 of FIG. 16 differs from the process 100-1 of FIG. 15 basically in that instead of the anodically pre-bonded aluminum film 14, an AlCu roll-plated sheet 14 (film) is used, wherein this sheet 14 may optionally also be anodically bonded to the substrate 12.

As step 140 also melts a portion of the copper of the AlCu sheet 14, the channel structures (holes) 12-1 may be filled with an AlCu alloy by AlCu eutectic formation to obtain the conductive channel structures 12-2 in the substrate.

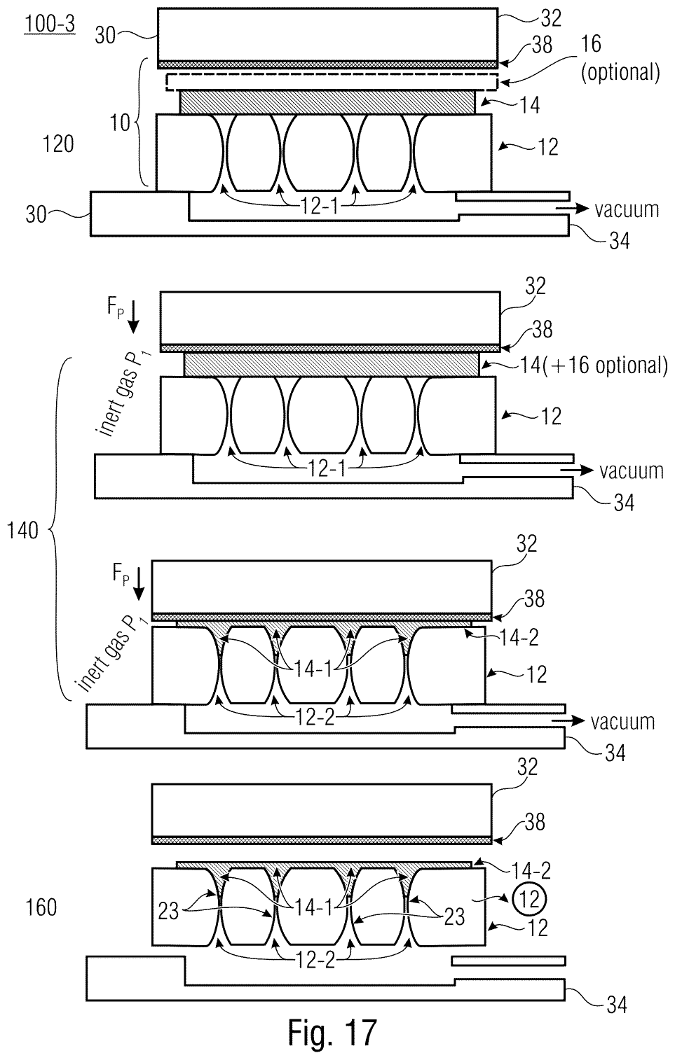

Referring to FIG. 17, a further, exemplary, principal flow diagram 100-3 of the manufacturing method 100 for manufacturing an electrically conductive channel structure 12-2 in a substrate 12 by introducing a metallic filling material 14-1 in accordance with a further embodiment will be described.

In the process flow 100-3, for example, an aluminum film 14 anodically pre-bonded on a glass wafer (glass substrate) 12 is used, wherein the perforated glass substrate 12 has, for example, a “Schott Af32 eco” material. Furthermore, a flow stop for the liquefied metal material 14-1 is created by the centrally narrowed hole geometry 23. The glass substrate 12 of FIG. 17 corresponds, for example, to the substrate 12 described with reference to FIG. 6I.

As will become clear in step 140, the molten aluminum material 14-1 is filled into the holes (channel structures) 12-1 to a certain degree, for example, wherein the degree of filling may be defined or adjusted by the hole geometry (the hole cross-section) and the atmospheric negative pressure (suction vacuum) provided.

Referring to FIG. 18, a further, exemplary, principal flow diagram 100-4 of the manufacturing method 100 for manufacturing an electrically conductive channel structure 12-2 in a substrate 12 by introducing a metallic filling material 14-1 in accordance with a further embodiment will be described.

In the process flow 100-4 of FIG. 18, a flow stop is generated by two laterally offset substrates (glass substrates) 12, 12′. For this purpose, in step 120, a perforated substrate (glass wafer) 12 is arranged to be offset on a similarly perforated substrate 12′ (e.g. with a non-stick coating therebetween), wherein suction channels 12-1 having a flow-stop effect are produced at the narrow sections 23.

In step 140, the liquefied metal (aluminum) 14-1 of the applied metal film 14 is thus mechanically pressed to be planar-acting with the (e.g. coated upper stop) 32 (first tool), wherein the heating may take place, for example, in a non-reactive gas atmosphere (N₂, Ar, etc.). In step 140 (melting of the aluminum film in a non-reactive gas atmosphere having a suction vacuum applied), the channel structure 12-1 of the substrate 12 is filled up to the narrow section 23 acting as a flow stop.

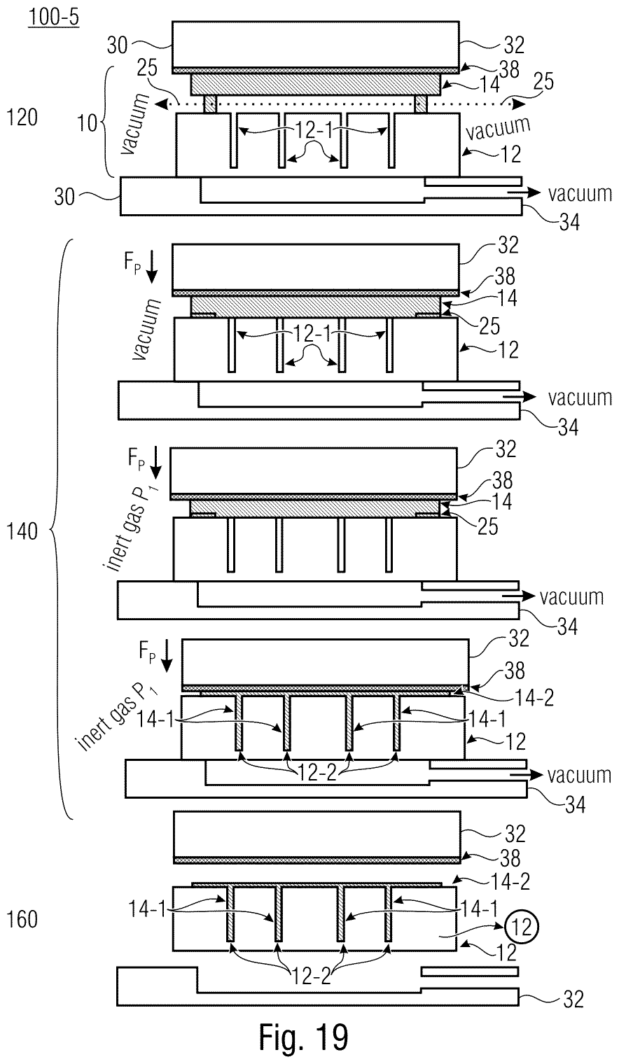

In the following, a further, exemplary, principal flow diagram 100-5 of the manufacturing method 100 for manufacturing an electrically conductive channel structure 12-2 in a substrate 12 by introducing a metallic filling material 12 in accordance with a further embodiment will be described with reference to FIG. 19.

In the process flow 100-5, the channel structures (blind holes) 12-1 in the substrate are evacuated by a procedure with melting spacers 25.

In step 120, a perforated substrate (perforated glass wafer) 12 is placed on a vacuum chuck (second tool) 34 and sucked on, the aluminum film 14 being placed on the substrate 12 with (laterally spaced) spacers 25, the gap/spacing between the aluminum film 14 and the substrate 12 and the channel structures 12-1 being evacuated via the chamber vacuum.

In step 140, the upper stop (first tool) 32 is pressed to be planar-acting and heated until the spacers 25 melt in the vacuum. As a result, the vacuum (atmospheric negative pressure) in the channel structures (blind holes) 12-1 remains gas-tightly enclosed by the pressed-on aluminum film 14.

The process chamber may optionally be flooded with an inert gas to support pressing the aluminum film 14 against the substrate 12. By heating to the process temperature, the metal material (aluminum) of the metal film 14 melts and runs into the evacuated channel structures (hole structures) 12-1.

After cooling and ventilating the process chamber and turning off the vacuum suction, the substrate 12 (the filled wafer) provided with the electrically conductive channel structures 12-2 can be removed in step 116.

Referring to FIG. 20, a further, exemplary, principle flow diagram 100-6 of the manufacturing method 100 for manufacturing an electrically conductive channel structure 12-2 in a substrate 12 by introducing a metallic filling material 12 in accordance with a further embodiment is described below.

In the process flow 100-6 illustrated with reference to FIG. 20, the aluminum foil 14 may be attached by a thin-film soldering process.

In step 120, a substrate 12 (perforated glass wafer) provided with the channel structures 12-1 with, for example, an AlGe solder coating 27 facing upward is placed on the second tool (vacuum chuck) 34 and sucked, whereupon the aluminum film 14 is placed on the coated substrate 12. In step 140, pressing (mechanical pressure) is established with the upper coated stop (first tool) 32 in the vacuum environment and the upper stop 32 is heated to produce an eutectic AlGe solder of the AlGe braze coating 27 with the Al film 14.

During heating to the process temperature T_{P}, the aluminum film is then melted completely and introduced (allowed to flow) into the (optionally stepped) channel structures (blind holes) 12-1 in the substrate 12.

In step 160, the filled substrate (the filled wafer) 12 may then be removed after the process chamber has cooled and ventilated and the vacuum suction has been switched off.

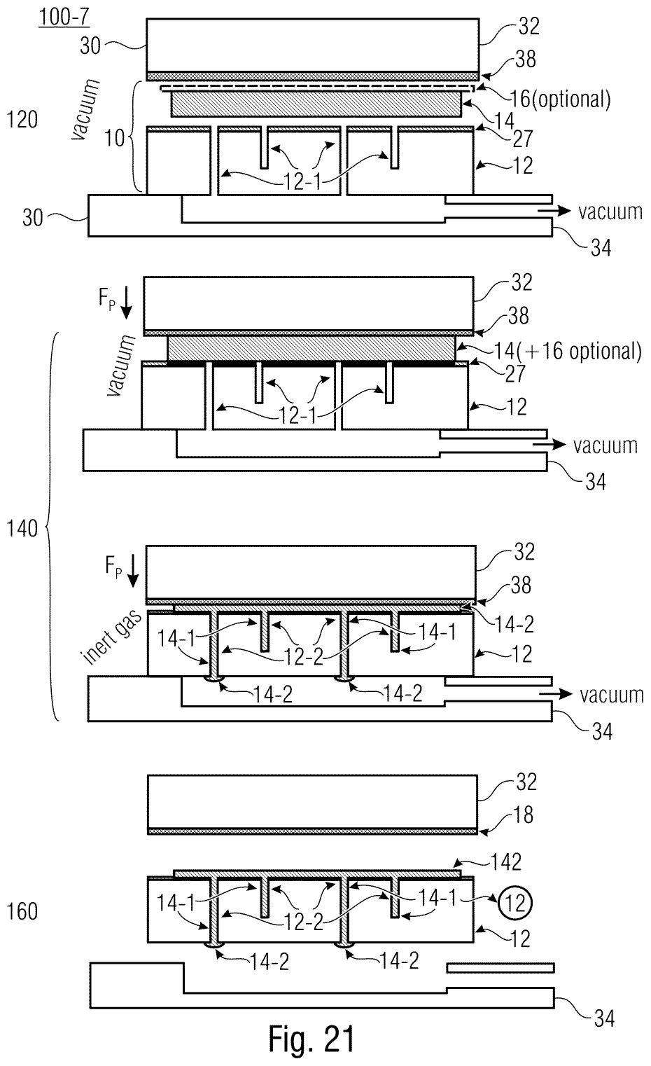

Referring to FIG. 21, a further, exemplary, principle flow diagram 100-7 of the manufacturing method 100 for manufacturing an electrically conductive channel structure 12-2 in a substrate 12 by introducing a metallic filling material 12 in accordance with a further embodiment is described below.

The process 100-7 of FIG. 21 differs from the process 100-6 of FIG. 20 in that the substrate (e.g. a perforated glass wafer) 12 has channel structures 12-1 in the form of blind holes and in the form of feedthroughs. According to the process flow 100-7, the channel structures 12-1 configured both as feedthroughs and as blind holes in the substrate 12 can be filled with the molten metal.

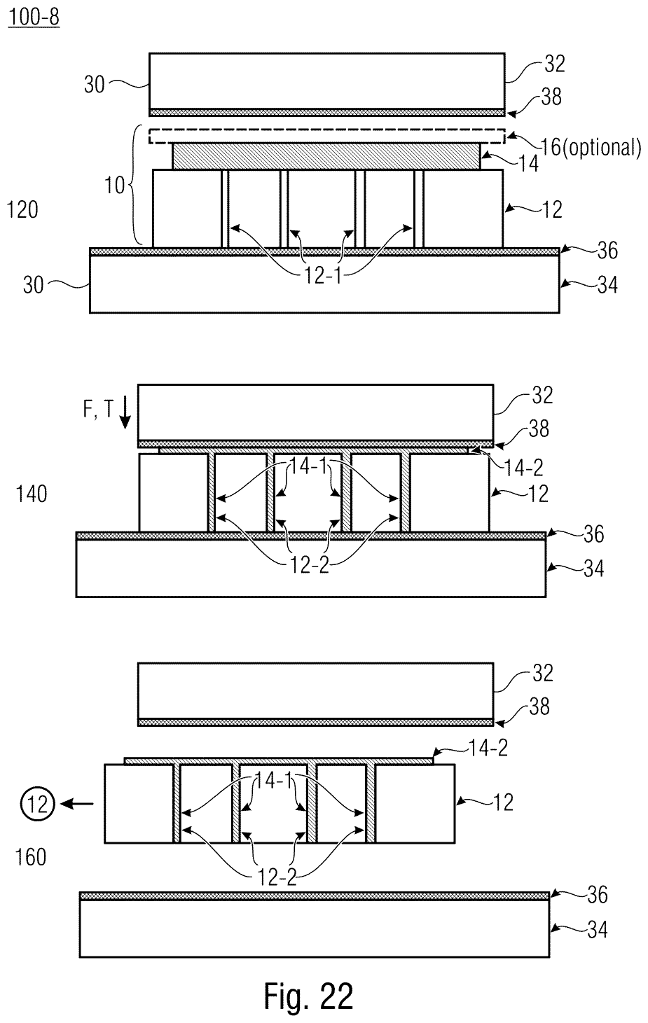

Referring to FIG. 22, a further, exemplary, principle flow diagram 100-8 of the manufacturing method 100 for manufacturing an electrically conductive channel structure 12-2 in a substrate 12 by introducing a metallic filling material 12 in accordance with a further embodiment will be described below.

In the process flow 100-8 shown in FIG. 22, an aluminum pressure melt filling is performed with a flow stop through the counter substrate 34 (without using a surface seal 16). In step 120, a substrate 12 (a perforated glass wafer) provided with channel structures 12-1 is arranged on a counter substrate (second tool) 34 coated with a rough non-stick layer 36.

In step 140, the channel structures 12-1 are pressure-filled with a flow-stop effect on the surface of the counter substrate 34. In step 160, the substrate (glass substrate) 12 equipped with aluminum TGVs can be removed.

Although some aspects of the present disclosure have been described as features related to an apparatus, it is clear that such a description may also be considered to be a description of corresponding features of a method. Although some aspects have been described as features related to a method, it is clear that such a description may also be considered to be a description of corresponding features of an apparatus or functionality of an apparatus. Some or all of the method steps may be performed by (or using) a hardware apparatus, such as a microprocessor, a programmable computer, or an electronic circuit. In some embodiments, some or several of the method steps may be executed by such an apparatus.

Depending on particular implementation requirements, embodiments of the invention may be implemented in hardware or in software or at least partially in hardware or at least partially in software.

In the foregoing detailed description, various features have been partly grouped together in examples to rationalize the disclosure. This tape of disclosure is not to be interpreted as intending the claimed examples to comprise more features than are expressly indicated in each claim. Rather, as the following claims reflect, subject-matter may lie in fewer than all of the features of a single example disclosed. Consequently, the following claims are hereby incorporated by reference into the detailed description, wherein each claim may stand as its own separate example. While each claim may stand as its own separate example, it is to be noted that although dependent claims in the claims refer back to a specific combination with one or more other claims, other examples also include a combination of dependent claims with the subject-matter of any other dependent claim or a combination of any feature with other dependent or independent claims. Such combinations are included unless it is stated that a specific combination is not intended. It is further intended for a combination of features of a claim with any other independent claim to be also included, even if that claim is not directly dependent on the independent claim.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A method for manufacturing an electrically conductive channel structure in a substrate, comprising:
providing a stack arrangement in a clamping device, the stack arrangement comprising a substrate provided with a channel structure, a metal film comprising an aluminum material on the substrate, and a compressible sealing element configured to surround the metal film at least laterally while exerting pressure,
exerting a planar-acting mechanical process pressure and a process temperature on the stack arrangement with the clamping device in order to melt the metal film comprising the aluminum material at the process temperature and to introduce it into the channel structure as metallic filling material by means of the planar-acting mechanical process pressure, and
cooling the stack arrangement to solidify the introduced metallic filling material and to acquire the electrically conductive channel structure filled with the metallic filling material.

2. The method according to claim 1, wherein the channel structure is configured as at least one through-hole structure, as at least one blind-hole structure or as at least one 3D structure in the substrate.

3. The method according to claim 1, wherein the metal film comprises the aluminum material as the main component (≥80%) for a resulting melting point of at least 420° C. or between 420° C. and 850° C.

4. The method according to claim 1, wherein the process temperature is set to a value of at least 10 K above the melting temperature of the metal film comprising the aluminum material.

5. The method according to claim 1, wherein the channel structure comprises a wall coating comprising a nitride material, with a thickness in a range from 5 to 100 nm.

6. The method according to claim 1, wherein the compressible sealing element is configured as a reusable high-temperature gasket.

7. The method according to claim 1, wherein the compressible sealing element is configured as a compressible surface sealing element, and wherein the surface sealing element covers the metal film and comprises a lateral projection in order to enclose the metal film up to the substrate when exerting the mechanical process pressure.

8. The method according to claim 7, wherein the surface sealing element comprises a graphite film with a thickness in a range from 0.3 to 1 mm or of about 0.5 mm.

9. The method according to claim 1, wherein the compressible sealing element is configured as a compressible ring sealing element, and wherein the ring sealing element surrounds the edge region of the metal film and laterally encloses the metal film while exerting pressure.

10. The method according to claim 9, wherein the ring sealing element comprises a structured graphite film with a thickness in a range from 0.3 to 1 mm or of about 0.5 mm.

11. The method according to claim 1, wherein the clamping arrangement comprises a first and a second tool, and wherein the stack arrangement is arranged between the first and second tools.

12. The method according to claim 1, wherein applying mechanical pressure between the first and second tools is performed at a contact pressure in a range from 10 N/cm² to 600 N/cm².

13. The method according to claim 11, wherein the first and/or second tool is configured to heat the stack arrangement to the process temperature.

14. The method according to claim 11, wherein the first tool is configured as a press punch and the second tool is configured as a counter substrate, wherein a main surface region of the second tool facing the substrate comprises a surface roughness with a center roughness value Rₐ or an average roughness depth R_{Z} between 0.5 and 10 μm or of about 3 μm.

15. The method according to claim 14, wherein the main surface region of the second tool facing the substrate comprises a coating to provide the surface roughness of the main surface region of the second tool facing the substrate.

16. The method according to claim 14, wherein the coating comprises a boron nitride material.

17. The method according to claim 14, wherein the surface roughness of the main surface region of the second tool adjacent to the substrate is selected to be effective as a flow stop for the molten metal, and to allow lateral escape of gas present in the channel structure.

18. The method according to claim 1 wherein the substrate comprises a glass, quartz, sapphire, ceramic or semiconductor material.

19. The method according to claim 1, further comprising:
removing excess metallic filling material on one side of one main surface region or on both sides of both opposing main surface regions of the substrate.

20. The method according to claim 19, wherein removing the excess material is performed by means of a CMP (chemical mechanical polishing) process.

21. The method according to claim 1, further comprising:
removing the stack arrangement from the clamping arrangement, and
removing the sealing element from the substrate.

22. The method according to claim 1, further comprising:
performing metallization on one or both sides by means of a thin-film deposition process to acquire a metallization structure electrically connected to the conductive channel structure on one or both main surface regions of the substrate configured with the conductive channel structure, via a lithographic patterning process and a subsequent etching step.

23. An interposer arrangement, comprising:
a substrate comprising an electrically and/or thermally conductive channel structure extending at least partially through the substrate,
wherein the channel structure comprises an aluminum material or an aluminum material alloy, and wherein the channel structure extends from a main surface region of the substrate into the substrate, and
wherein the aluminum material or the aluminum material alloy comprises aluminum as the main component of at least 80% in order to comprise a resulting melting point of at least 420° C. or between 420° C. and 850° C. as brazing hard solder.

24. The interposer arrangement according to claim 23, wherein the conductive channel structure extends from one main surface region of the substrate into the substrate and to the opposite main surface region of the substrate.

25. The interposer arrangement according to claim 23, wherein the conductive channel structure does not extend, at least in sections, in a direction vertical to the two opposite main surface regions of the substrate.

26. The interposer arrangement according to claim 23, wherein the channel structure comprises an aluminum material or an aluminum material alloy, and wherein the conductive channel structure extends vertically to the two opposite main surface regions of the substrate.

27. The interposer arrangement according to claim 26, wherein the conductive channel structure is configured as at least one thermal connection for heat dissipation through the substrate.

28. The interposer arrangement according to claim 23, wherein the conductive channel structure is configured as at least one electrical via through the substrate and/or as at least one passive component in the substrate.

29. The interposer arrangement according to claim 28, wherein the at least one via through the substrate comprises an aspect ratio of 50:1 of length to diameter.

30. The interposer arrangement according to claim 23, wherein the interposer arrangement is manufactured by a method for manufacturing an electrically conductive channel structure in a substrate, comprising:
providing a stack arrangement in a clamping device, the stack arrangement comprising a substrate provided with a channel structure, a metal film comprising an aluminum material on the substrate, and a compressible sealing element configured to surround the metal film at least laterally while exerting pressure,
exerting a planar-acting mechanical process pressure and a process temperature on the stack arrangement with the clamping device in order to melt the metal film comprising the aluminum material at the process temperature and to introduce it into the channel structure as metallic filling material by means of the planar-acting mechanical process pressure, and
cooling the stack arrangement to solidify the introduced metallic filling material and to acquire the electrically conductive channel structure filled with the metallic filling material.
